(19) United States
(12) Patent Application Publication
(10) Pub. No.: US 2025/0391441 A1
(43) Pub. Date: Dec. 25, 2025

(54) SEMICONDUCTOR MEMORY DEVICE

(71) Applicant: SK hynix Inc., Icheon-si Gyeonggi-do (KR)

(72) Inventors: Seok Min CHOI, Icheon-si Gyeonggi-do (KR); Jung Shik JANG, Icheon-si Gyeonggi-do (KR); Rho Gyu KWAK, Icheon-si Gyeonggi-do (KR); Mi Seong PARK, Icheon-si Gyeonggi-do (KR); In Su PARK, Icheon-si Gyeonggi-do (KR); Na Yeong YANG, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 19/035,485

(22) Filed: Jan. 23, 2025

(30) Foreign Application Priority Data
Jun. 24, 2024 (KR) 10-2024-0081982

(51) Int. Cl. G11C 5/06; G11C 16/04; H10B 41/10; H10B 41/27; H10B 43/10; H10B 43/27

(52) U.S. Cl. CPC G11C 5/063; G11C 16/0483; H10B 41/10; H10B 41/27; H10B 43/10; H10B 43/27

(57) ABSTRACT

A semiconductor memory device includes a plurality of conductive layers arranged in a vertical direction, a plurality of active layers connected to the plurality of conductive layers, a plurality of pass gates each penetrating the plurality of active layers, and a plurality pass gate insulating layers surrounding sidewalls of the plurality of pass gates, respectively.

### CROSS-REFERENCE TO RELATED APPLICATION

The present application claims priority under 35 U.S.C. § 119(a) to Korean patent application number 10-2024-0081982 filed on Jun. 24, 2024, in the Korean Intellectual Property Office, the entire contents of which application is incorporated herein by reference.

### BACKGROUND

### 1. Technical Field

The present disclosure generally relates to a semiconductor memory device and an electronic system including the semiconductor memory device, and more particularly, to a three-dimensional semiconductor memory device and an electronic system including the three-dimensional semiconductor memory device.

### 2. Related Art

Semiconductor memory devices are applied to electronic systems in various fields, including automobiles, medical appliances, data centers, and the like, in addition to compact electronic devices. Accordingly, demands for semiconductor memory devices have increased.

A semiconductor memory device may include a memory cell for data storage. A three-dimensional semiconductor memory device includes a plurality of three-dimensionally arranged memory cells, to be advantageous for mass storage as compared with two-dimensional semiconductor memory devices.

The degree of integration of memory cells in the three-dimensional semiconductor device may be improved by increasing the stacked number of memory cells. When the stacked number of memory cells is increased, the stacked number of conductive layers connected to a memory cell may be increased. As the stacked number of conductive layers is increased, the area occupied by a peripheral circuit structure which controls a stack structure of conductive layers may be increased.

### SUMMARY

According to an embodiment of the present disclosure, a semiconductor memory device may include a plurality of cell pillar structures extending in a vertical direction, the plurality of cell pillar structures being arranged to be spaced apart from each other in a horizontal direction; a word line stack structure surrounding the plurality of cell pillar structures, the word line stack structure including a plurality of cell gate layers arranged to be spaced apart from each other in the vertical direction; a plurality of cell level contact conductive layers spaced apart from the plurality of cell gate layers in the horizontal direction, the plurality of cell level contact conductive layers being arranged to be spaced apart from each other in the vertical direction; a plurality of cell level active layers connected to the plurality of cell gate layers, the plurality of cell level active layers extending in the horizontal direction to be connected to the plurality of cell level contact conductive layers, the plurality of cell level active layers being arranged to be spaced apart from each other in the vertical direction; a plurality of pass gates spaced apart from each other in the horizontal direction, each of the plurality of pass gates penetrating the plurality of cell level active layers; a plurality of pass gate insulating layers surrounding sidewalls of the plurality of pass gates, respectively; and a plurality of insulative pillar structures alternately disposed one by one in the horizontal direction with the plurality of pass gates, the plurality of insulative pillar structures penetrating the plurality of cell level active layers.

According to an embodiment of the present disclosure, a semiconductor memory device may include a source layer having a first surface and a second surface, which face in directions opposite to each other and extend in a horizontal direction; a bit line disposed to be spaced apart from the second surface of the source layer in a vertical direction; a plurality of insulating layers including a local region, a global region spaced apart from the local region in the horizontal direction, and a pass transistor array region between the local region and the global region, the plurality of insulating layers being spaced apart from each other in the vertical direction between the second surface of the source layer and the bit line; a plurality of first conductive layers alternately disposed one by one in the vertical direction with the plurality of insulating layers in the local region; a plurality of cell pillar structures penetrating the plurality of first conductive layers and the plurality of insulating layers; a plurality of active layers alternately disposed one by one in the vertical direction with the plurality of insulating layers in the pass transistor array region; a plurality of pass gates each including a first end portion facing in the same direction as the first surface of the source layer and a second end portion facing in the same direction as the second surface of the source layer, each of the plurality of pass gates penetrating the plurality of active layers and the plurality of insulating layers; and a plurality of pass gate insulating layers surrounding sidewalls of the plurality of pass gates, respectively, wherein the first end portion of each of the plurality of pass gates is disposed closer to the plurality of insulating layers than the first surface of the source layer.

### BRIEF DESCRIPTION OF THE DRAWINGS

In the drawing figures, dimensions may be exaggerated for clarity of illustration. Like reference numerals refer to like elements throughout.

FIG. 1 is a block diagram illustrating a semiconductor memory device in accordance with an embodiment of the present disclosure.

FIGS. 2A and 2B are circuit diagrams illustrating a memory cell array and a pass circuit in accordance with embodiments of the present disclosure.

FIGS. 3, 4A, 4B, and 4C are views illustrating a semiconductor memory device in accordance with an embodiment of the present disclosure.

FIGS. 5 and 6 are views illustrating a semiconductor memory device in accordance with an embodiment of the present disclosure.

FIG. 7 is a plan view illustrating a semiconductor memory device in accordance with an embodiment of the present disclosure.

FIGS. 8A and 8B are sectional views illustrating a semiconductor memory device in accordance with an embodiment of the present disclosure.

FIG. 9 is a plan view illustrating a semiconductor memory device in accordance with an embodiment of the present disclosure.

FIG. 10 is a sectional view illustrating a global region of a stack structure in accordance with an embodiment of the present disclosure.

FIG. 11 is a sectional view illustrating a semiconductor memory device in accordance with an embodiment of the present disclosure.

FIGS. 12A, 12B, 13A, 13B, 14A, 14B, 15A, 15B, 16A, 16B, 17A, 17B, 17C, 18, 19, 20A, 20B, 21A, 21B, 21C, 22A, 22B, and 23 are views illustrating a method of manufacturing a semiconductor memory device in accordance with an embodiment of the present disclosure.

FIGS. 24A, 24B, and 24C are sectional views illustrating a method of manufacturing a semiconductor memory device in accordance with an embodiment of the present disclosure.

FIGS. 25A and 25B are views illustrating a semiconductor memory device in accordance with an embodiment of the present disclosure.

FIG. 26 is a block diagram illustrating an electronic system in accordance with embodiments of the present disclosure.

### DETAILED DESCRIPTION

Specific structural or functional I descriptions of the embodiments according to the concept of the present disclosure disclosed in the present specification or application are exemplified to describe the embodiments according to the concept of the present disclosure. The embodiments according to the concept of the present disclosure are not to be construed as being limited to the embodiments described in the present specification or application, and may be variously modified and replaced with other equivalent embodiments.

It will be understood that, although the terms “first,” “second,” etc. may be used herein to describe various elements, these elements should not be limited by these terms. These terms are only used to distinguish one element from another element, and the order or number of components is not limited by the terms. In addition, it is not construed as limiting the number of components unless there is a special limitation on components expressed in singular or plural numbers. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. The cross-hatching throughout the figures illustrates corresponding or similar areas between the figures rather than indicating the materials for the areas.

Various embodiments may provide a semiconductor memory device capable of reducing the area occupied by a peripheral circuit structure.

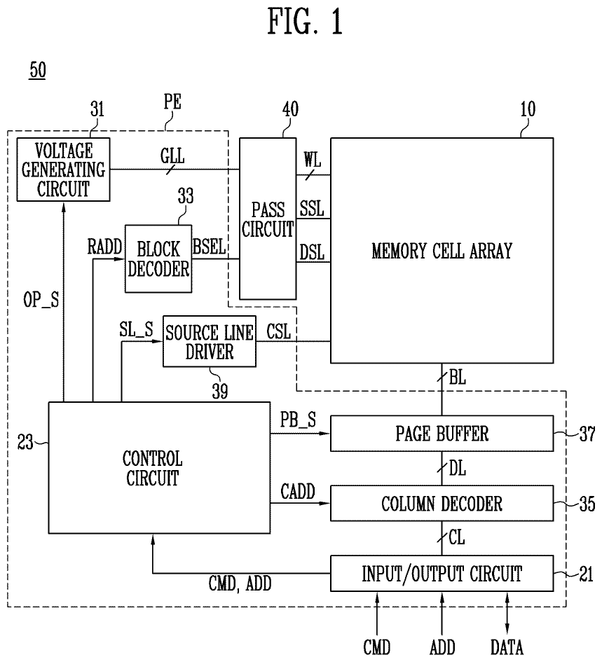

FIG. 1 is a block diagram illustrating a semiconductor memory device in accordance with an embodiment of the present disclosure.

Referring to FIG. 1, the semiconductor memory device 50 may include a memory cell array 10, a pass circuit 40, and a peripheral circuit structure PE.

The memory cell array 10 may include a plurality of memory blocks. Each memory block may include a plurality of memory cells. Each memory cell may be a nonvolatile memory cell. In an embodiment, each memory cell may be a NAND flash memory cell.

The pass circuit 40 may be connected to the memory cell array 10 through local lines. The local lines may include a plurality of word lines WL, a plurality of source select lines SSL, and a plurality of drain select lines DSL.

The peripheral circuit structure PE may be configured to perform a program operation for storing data in the memory cell array 10, a read operation for outputting data stored in the memory cell array 10, and an erase operation for erasing data stored in the memory cell array 10. In an embodiment, the peripheral circuit structure PE may include an input/output circuit 21, a control circuit 23, a voltage generating circuit 31, a block decoder 33, a column decoder 35, a page buffer 37, and a source line driver 39.

The input/output circuit 21 may transfer, to the control circuit 23, a command CMD and an address ADD, which are received from an external device (e.g., a memory controller) of the semiconductor memory device 50. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate and output various operating voltages used for a program operation, a read operation, and an erase operation in response to the operation signal OP_S. The operating voltages output from the voltage generating circuit 31 may be transmitted to the pass circuit 40 through a plurality of global lines GLL.

The block decoder 33 may output block select signals in response to the row address RADD. The block select signals output from the block decoder 33 may be transmitted to the pass circuit 40 through block select lines BSEL. The pass circuit 40 may include a plurality of pass transistor groups respectively corresponding to the plurality of memory blocks of the memory cell array 10. Each block select line BSEL may be connected to a corresponding pass transistor group among the plurality of pass transistor groups of the pass circuit 40. Each pass transistor group may transfer the operation voltages transmitted to the plurality of global lines GLL to a drain select line DSL, a word line WL, and a source select line SSL, which are connected to a corresponding memory block, in response to block select signal corresponding thereto.

The column decoder 35 may transmit data DATA input from the input/output circuit 21 to the page buffer 37 or transmit data DATA stored in the page buffer 37 to the input/output circuit 21 in response to the column address CADD. The column decoder 35 may exchange data DATA with the input/output circuit 21 through column lines CL. The column decoder 35 may exchange data DATA with the page buffer 37 through data lines DL.

The page buffer 37 may store read data received through bit lines BL in response to the page buffer control signal PB_S. The page buffer 37 may sense a voltage or current of the bit lines BL in a read operation. The page buffer 37 may be connected to the memory cell array 10 through the bit lines BL.

The source line driver 39 may control a voltage applied to a common source line CSL in response to the source line control signal SL_S. The source line driver 39 may be connected to the memory cell array 10 through the common source line CSL.

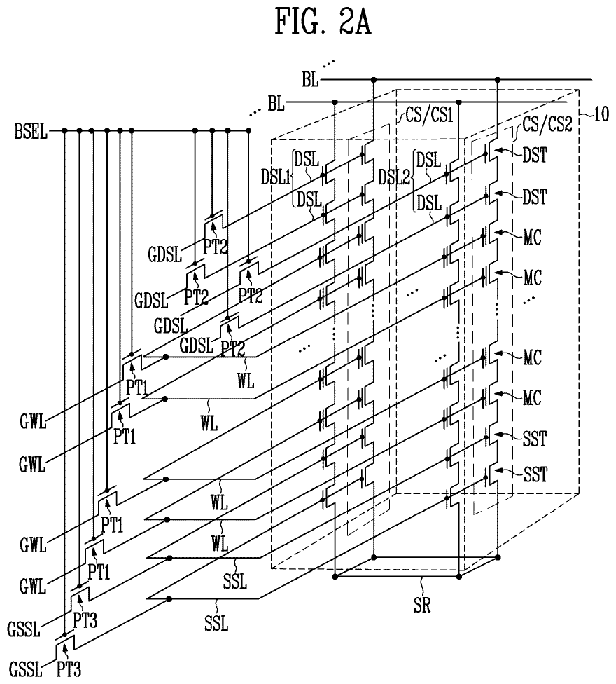

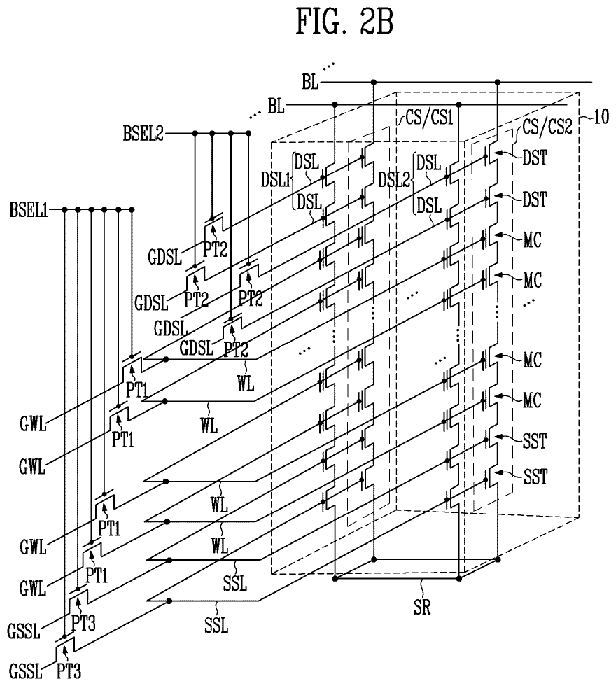

FIGS. 2A and 2B are circuit diagrams illustrating a memory cell array and a pass circuit in accordance with embodiments of the present disclosure.

Referring to FIGS. 2A and 2B, each memory block in the memory cell array 10 may include a plurality of memory cell strings CS. The plurality of memory cell strings CS may be connected to a plurality of bit lines BL and a source layer SR. The plurality of memory cell strings CS may be connected to the common source line CSL shown in FIG. 1 via the source layer SR.

Each memory cell string CS may include at least one source select transistor SST, a plurality of memory cells MC, and at least one drain select transistor DST.

The source select transistor SST may control an electrical connection between the plurality of memory cells MC and the source layer SR. The drain select transistor DST may control an electrical connection between the plurality of memory cells MC and a bit line BL.

One source select transistor SST or two or more source select transistors SST connected in series may be disposed between the source layer SR and the plurality of memory cells MC. One drain select transistor DST or two or more drain select transistors DST connected in series may be disposed between each bit line BL and a plurality of memory cells MC of a memory cell string CS corresponding thereto.

A plurality of cell gate layers of the plurality of memory cells MC may be connected to a plurality of word lines WL, respectively. A source select gate of the source select transistor SST may be connected to a source select line SSL. A drain select gate of the drain select transistor DST may be connected to a drain select line DSL.

The plurality of memory cell strings CS may include a first memory cell string CS1 and a second memory cell string CS2, which are connected in parallel to one word line WL and one bit line BL. The first memory cell string CS1 and the second memory cell string CS2 may be connected to one source select line SSL, and be individually connected to a first drain select line group DSL1 and a second drain select line group DSL2, which are isolated from each other. However, embodiments of the present disclosure are not limited thereto. Although not shown in the drawings, in an embodiment, the first memory cell string CS1 and the second memory cell string CS may be individually connected to different source select line groups.

The source select line SSL, the drain select line DSL, and the plurality of word lines WL may be connected to pass transistors forming a portion of the pass circuit 40 shown in FIG. 1. The pass transistors may include a plurality of first pass transistors PT1 connected to the plurality of word lines WL, a second pass transistor PT2 connected to the drain select line DSL, and a third pass transistor PT3 connected to the source select line SSL.

The plurality of first pass transistors PT1, the second pass transistor PT2, and the third pass transistor PT3 may be connected to global lines GWL, GDSL, and GSSL. The global lines may include a plurality of global word lines GWL, a global drain select line GDSL, and a global source select line GSSL. The plurality of first pass transistors PT1, the second pass transistor PT2, and the third pass transistor PT3 may be connected to local lines WL, DSL, and SSL of a corresponding memory block. The local lines of the memory block may include a plurality of word lines WL, a drain select line DSL, and a source select line SSL. A source and a drain of each first pass transistor PT1 may be connected to a corresponding global word line GWL and a corresponding word line WL, respectively. A source and a drain of the second pass transistor PT2 may be connected to the global drain select line GDSL and the drain select line DSL, respectively. A source and a drain of the third pass transistor PT3 may be connected to the global source select line GSSL and the source select line SSL, respectively.

Gate electrodes of the plurality of first pass transistors PT1 may be connected to one block selection line BSEL or BSEL1. A gate electrode of the second pass transistor PT2 and a gate electrode of the third pass transistor PT3 may be connected to one block select line BSEL or be individually connected to different block select lines BSEL1 and BSEL1. In an embodiment, as shown in FIG. 2A, the gate electrode of the second pass transistor PT2 and a gate electrode of the third pass transistor PT3 may be connected to the block select line BSEL connected to the plurality of first pass transistor PT1. In another embodiment, as shown in FIG. 2B, the gate electrodes of the plurality of first pass transistors PT1 and the gate electrode of the third pass transistor PT3 may be connected to a first block select line BSEL1, and the gate electrode of the second pass transistor PT2 may be connected to a second block select line BSEL2.

Referring to FIGS. 2A and 2B, each of the plurality of first pass transistors PT1, the second path transistor PT2, and the third pass transistor PT3 may transfer voltages applied to the plurality of global word line GWL, the global drain select line GDSL, and the global source select line to the plurality of word lines WL, the drain select line DSL, and the source select line SSL in response to a block select signal applied to a block select line BSEL, BSEL1 or BSEL2 corresponding thereto.

The plurality of word lines WL, the drain select line DSL, and the source select line SSL may be configured with first conductive layers. The first conductive layers may include a word line stack structure including a plurality of cell gate layers forming the plurality of word lines WL. The plurality of first pass transistors PT1 may include a plurality of cell level active layers connected to the plurality of cell gate layers. The plurality of cell level active layers may form a stack structure corresponding to the word line stack structure.

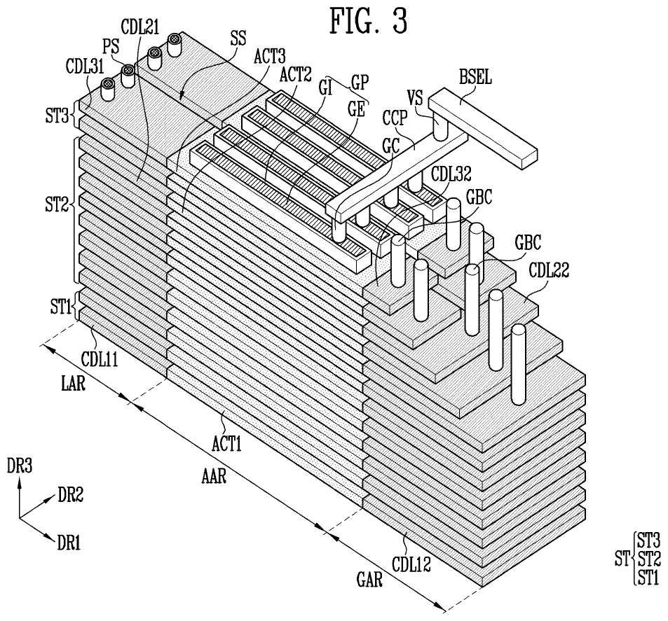

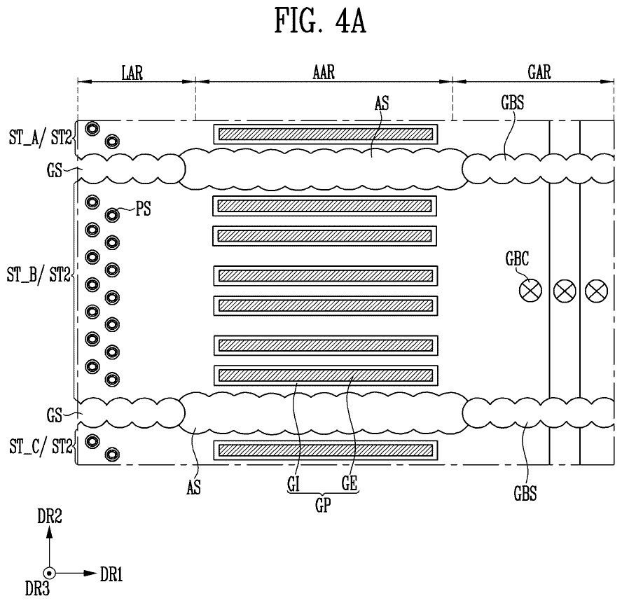

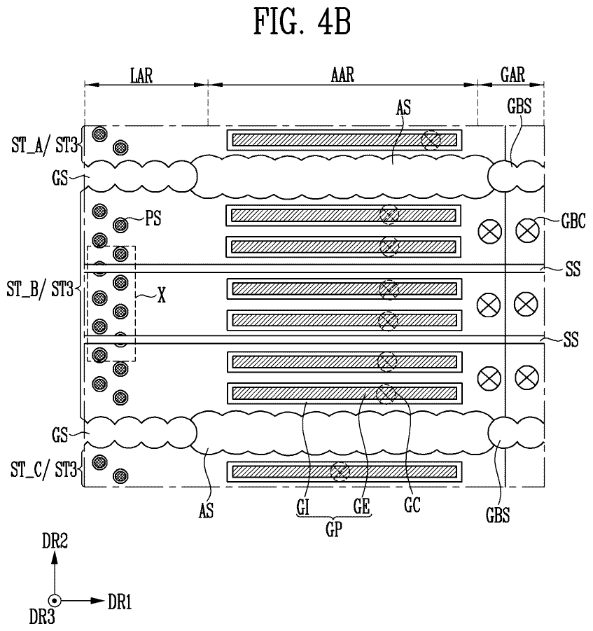

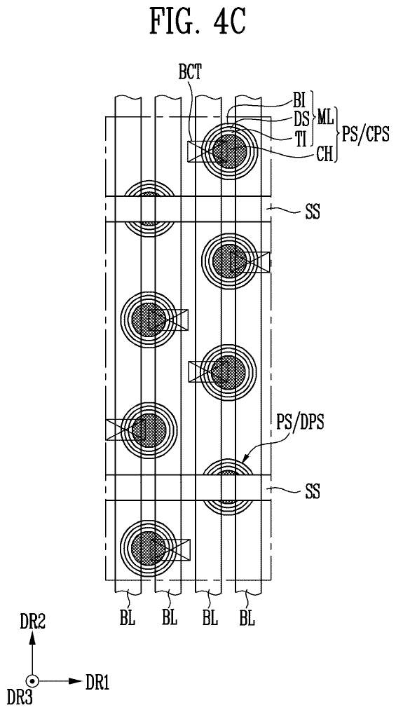

FIGS. 3, 4A, 4B, and 4C are views illustrating a semiconductor memory device in accordance with an embodiment of the present disclosure.

Referring to FIGS. 3, 4A, 4B, and 4C, a memory block of the semiconductor memory device may include a stack structure ST, ST_A, ST_B or ST_C, a plurality of pillar structures PS penetrating the stack structure ST, ST_A, ST_B or ST_C, a plurality of gate pillar structures GP penetrating the stack structure ST, ST_A, ST_B or ST_C, a plurality of conductive gate contact structures GC, a plurality of global conductive patterns GBC, a plurality of bit lines BL, a conductive connection pattern CCP, a conductive via structure VS, and a block select line BSEL. The stack structure ST, ST_A, ST_B or ST_C may include a plurality of insulating layers and a plurality of horizontal layers CDL11, CDL21, CDL31, ACT1, ACT2, ACT3, CDL12, CDL22, and CDL32, which extend in a horizontal direction. A first direction DR1 and a second direction DR2, which are shown in the drawings, are directions in which axes intersecting each other on a plane face, and each may be defined as the horizontal direction. Although not shown in FIG. 3, the plurality of insulating layers may be alternately disposed one by one with the plurality of horizontal layers CDL11, CDL21, CDL31, ACT1, ACT2, ACT3, CDL12, CDL22, and CDL32 in a vertical direction. A third direction DR3 shown in the drawings may be defined as the vertical direction. For example, the first direction DR1, the second direction DR2, and the third direction DR3 may correspond to an X-axis direction, a Y-axis direction, and a Z-axis direction, respectively.

The stack structure ST, ST_A, ST_B or ST_C may include a local region LAR, a pass transistor array region AAR, and a global region GAR. The global region GAR may be spaced apart from the local region LAR in the horizontal direction, and the pass transistor array region AAR may be disposed between the local region LAR and a global region GAR. In an embodiment, the local region LAR, the pass transistor array region AAR, and the global region GAR may be arranged in the first direction DR1. The global region GAR may be connected to the local region LAR via the pass transistor array region AAR. The stack structure ST, ST_A, ST_B or ST_C may include a first sub-stack structure ST1, a second sub-stack structure ST2, and a third sub-stack structure ST3, which are stacked in the third direction DR3.

FIG. 3 illustrates a portion of a stack structure ST forming the memory block.

Referring to FIG. 3, the stack structure ST may include a plurality of horizontal layers CDL11, CDL21, CDL31, ACT1, ACT2, ACT3, CDL12, CDL22, and CDL32 extending in the first direction DR1 and the second direction DR2. The plurality of horizontal layers CDL11, CDL21, CDL31, ACT1, ACT2, ACT3, CDL12, CDL22, and CDL32 may include a plurality of first conductive layers CDL11, CDL21, and CDL31, a plurality of active layers ACT1, ACT2, and ACT3, and a plurality of second conductive layers CDL12, CDL22, CDL32. Each of the plurality of first conductive layers CDL11, CDL21, and CDL31 and the plurality of second conductive layers CDL12, CDL22, CDL32 may include various conductive materials such as a doped semiconductor layer and a metal layer. The doped semiconductor layer may include a doped silicon layer. The metal layer may include tungsten, copper, molybdenum, and the like. Each of the plurality of first conductive layers CDL11, CDL21, and CDL31 and the plurality of second conductive layers CDL12, CDL22, CDL32 may further include a metal nitride layer provided as a barrier layer. The metal nitride layer may include titanium nitride, tantalum nitride, molybdenum nitride, and the like. Each of the plurality of active layers ACT1, ACT2, and ACT3 may include a semiconductor layer such as silicon, which serve as a channel layer.

The plurality of first conductive layers CDL11, CDL21, and CDL31 may be disposed in the local region LAR of the stack structure ST to be spaced apart from each other in the third direction DR3. The plurality of first conductive layers CDL11, CDL21, and CDL31 may include at least one source select gate layer CDL11 of the first sub-stack structure ST1, a plurality of cell gate layers CDL21 of the second sub-stack structure ST2, and at least one drain select gate layer CDL31 of the third sub-stack structure ST3. The source select gate layer CDL11 may serve as the source select line SSL shown in FIG. 2A, the plurality of cell gate layers CDL21 may serve as the plurality of word lines WL shown in FIG. 2A, and the drain select gate layer CDL31 may serve as the drain select line DSL shown in FIG. 2A.

The plurality of active layers ACT1, ACT2, and ACT3 may be disposed in the pass transistor array region AAR of the stack structure ST to be spaced apart from each other in the third direction DR3. The plurality of active layers ACT1, ACT2, and ACT3 may be substantially disposed at the same levels as the plurality of first conductive layers CDL11, CDL21, and CDL31, respectively. The plurality of active layers ACT1, ACT2, and ACT3 may be connected to the plurality of first conductive layers CDL11, CDL21, and CDL31. In an embodiment, the plurality of active layers ACT1, ACT2, and ACT3 may be adjacent to the plurality of first conductive layers CDL11, CDL21, and CDL31 in the first direction DR1, and may be connected to sidewalls of the plurality of first conductive layers CDL11, CDL21, and CDL31, respectively. The plurality of active layers ACT1, ACT2, and ACT3 may include at least one source select level active layer ACT1 of the first sub-stack structure ST1, a plurality of cell level active layers ACT2 of the second sub-stack structure ST2, and at least one drain select level active layer ACT3 of the third sub-stack structure ST3.

The plurality of second conductive layers CDL12, CDL22, and CDL32 may be disposed in the global region GAR of the stack structure ST to be spaced apart from each other in the third direction DR3. The plurality of second conductive layers CDL12, CDL22, and CDL32 may be substantially disposed at the same levels as the plurality of first conductive layers CDL11, CDL21, and CDL31, respectively. The plurality of second conductive layers CDL12, CDL22, and CDL32 may be spaced apart from the plurality of first conductive layers CDL11, CDL21, and CDL31 in the horizontal direction, and be connected to the plurality of active layers ACT1, ACT2, and ACT3. In an embodiment, the plurality of second conductive layers CDL12, CDL22, and CDL32 may be spaced apart from the plurality of first conductive layers CDL11, CDL21, and CDL31 in the first direction DR1, and be adjacent to the plurality of active layers ACT1, ACT2, and ACT3 in the first direction DR1. The plurality of second conductive layers CDL12, CDL22, and CDL32 may be connected to sidewalls of the plurality of active layers ACT1, ACT2, and ACT3, respectively. The plurality of second conductive layers CDL12, CDL22, and CDL32 may include at least one source select level contact conductive layer CDL12 of the first sub-stack structure ST1, a plurality of cell level contact conductive layers CDL22 of the second sub-stack structure ST2, and at least one drain select level contact conductive layer CDL32 of the third sub-stack structure ST3.

FIGS. 4A and 4B are plan views illustrating stack structure ST_A, stack structure ST_B, and stack structure ST_C, which are spaced apart from each other. The stack structure ST_A and the stack structure ST_C are adjacent to each other in the second direction DR2 with the stack structure ST_B interposed therebetween. In FIGS. 4A and 4B, the stack structure ST_B is mainly illustrated, and a partial region of each of the stack structure ST_A and the stack structure ST_C, which is adjacent to the stack structure ST_B, is illustrated. FIG. 4A illustrates a layout of the second sub-stack structure ST2 in each stack structure ST_A, ST_B or ST_C, and FIG. 4B illustrates a layout of the third sub-stack structure ST3 in each stack structure ST_A, ST_B or ST_C. The stack structure ST shown in FIG. 3 may correspond to a portion of each of the stack structure ST_A, the stack structure ST_B, and the stack structure ST_C, which are shown in FIGS. 4A and 4B.

Referring to FIGS. 4A and 4B, the semiconductor memory device may include first isolation structures AS, second isolation structures GS, and third isolation structures GBS, which partition the stack structures ST_A, ST_B, and ST_C. The first isolation structures AS, the second isolation structures GS, and the third isolation structures GBS may form isolation groups. Each isolation group may include one corresponding first isolation structure AS, one corresponding second isolation structure GS, and one corresponding third isolation structure GBS. The first isolation structure AS, the second isolation structure GS, and the third isolation structure GBS in each isolation group may be arranged in a line in an arrangement direction of the local region LAR, the pass transistor array region AAR, and a global region GAR. In an embodiment, the first isolation structure AS, the second isolation structure GS, and the third isolation structure GBS in each isolation group may be arranged in a line in the first direction DR1. A sidewall of each stack structure ST_A, ST_B or ST_C may be defined along sidewalls of the first isolation structure AS, the second isolation structure GS, and the third isolation structure GBS, which are arranged in a line in the first direction DR1. The sidewall of each of the first isolation structure AS, the second isolation structure GS, and the third isolation structure GBS may include unevenness, and the unevenness defined along the sidewall of each of the first isolation structure AS, the second isolation structure GS, and the third isolation structure GBS may be formed at the sidewall of each stack structure ST_A, ST_B or ST_C.

Each stack structure ST_A, ST_B or ST_C may include the plurality of active layers ACT1, ACT2, and ACT3 shown in FIG. 3, and the first isolation structures AS may be adjacent to each other in the second direction DR2 with the plurality of active layers ACT1, ACT2, and ACT3 shown in FIG. 3, which are interposed therebetween. Each stack structure ST_A, ST_B or ST_C may include the plurality of first conductive layers CDL11, CDL21, and CDL31 shown in FIG. 3, and the second isolation structures GS may be adjacent to each other in the second direction DR2 with the plurality of first conductive layers CDL11, CDL21, and CDL31 shown in FIG. 3, which are interposed therebetween. The second isolation structures GS may be connected to the first isolation structures AS, respectively. Each stack structure ST_A, ST_B or ST_C may include the plurality of second conductive layers CDL12, CDL22, and CDL32 shown in FIG. 3, and the third isolation structures GBS may be adjacent to each other in the second direction DR2 with the plurality of second conductive layers CDL12, CDL22, and CDL32 shown in FIG. 3, which are interposed therebetween. The third isolation structures GBS may be connected to the first isolation structures AS, respectively.

Referring to FIGS. 3, 4A, and 4B, the third sub-stack structure ST3 may be penetrated by a select isolation structure SS. A depth of the select isolation structure SS may be designed such that the select isolation structure SS does not penetrate the first sub-stack structure ST1 and the second sub-stack structure ST2. In the third sub-stack structure ST3, each drain select gate layer CDL31 may be isolated into the drain select lines DSL shown in FIG. 2A by the select isolation structure SS. The select isolation structure SS may extend in the first direction DR1 to penetrate the drain select level active layer ACT3 and the drain select level contact conductive layer CDL32. Accordingly, the drain select level active layer ACT3 may be isolated into sub-active layers respectively corresponding to the drain select lines by the select isolation structure SS, and the drain select level contact conductive layer CDL32 may be isolated into sub-contact conductive layers respectively corresponding to the drain select lines by the select isolation structure SS.

In the local region LAR, each stack structure ST, ST_A, ST_B or ST_C may be penetrated by a plurality of pillar structures PS. The plurality of pillar structures PS may extend in the third direction DR3 to penetrate the plurality of first conductive layers CDL11, CDL21, and CDL32.

FIG. 4C is an enlarged plan view of a plurality of pillar structure PS disposed in region X shown in FIG. 4B.

Referring to FIG. 4C, the plurality of pillar structures PS may include a plurality of cell pillar structures CPS (i.e., shown as “PS/CPS” in FIG. 4C). The plurality of cell pillar structures CPS may be arranged to be spaced apart from each other in the first direction DR1 and the second direction DR2. Each cell pillar structure CPS may be connected to a bit line BL corresponding thereto via a conductive bit line contact structure BCT.

The plurality of cell pillar structures CPS may be disposed on a plurality of rows and a plurality of columns. Cell pillar structures CPS of each row may be arranged in a line in the first direction DR1, and cell pillar structures CPS of each column may be arranged in a line in the second direction DR2. A select isolation structure SS may be disposed between some rows among the plurality of rows configured with the plurality of cell pillar structures CPS.

The plurality of pillar structures PS may further include dummy pillar structures DPS overlapping with the select isolation structure SS. However, various embodiments of the present disclosure are not limited thereto. In an embodiment, the dummy pillar structures DPS may be omitted, and the select isolation structure SS may overlap with a portion of each of cell pillar structures CPS arranged on two rows adjacent thereto.

Each pillar structure PS may include a memory layer ML and a channel structure CH. The memory layer ML may extend along a sidewall of the channel structure CH. The channel structure CH may serve as a channel structure of a memory cell string. The channel structure CH may be formed of a semiconductor material such as silicon (Si), germanium (Ge) or any mixture thereof. The memory layer ML may include a blocking insulating layer BI, a data storage layer DS, and a tunnel insulating layer TI. The tunnel insulating layer TI may extend along an outer wall of the channel structure CH, and include an insulating material such as a silicon oxide layer. The data storage layer DS may continuously extend in the third direction DR3 along an outer wall of the tunnel insulating layer TI, or be isolated into data storage patterns spaced apart from each other in the third direction DR3. The data storage patterns may be disposed at levels at which the first conductive layers CDL11, CDL21, and CDL31 shown in FIG. 3 are disposed, respectively. The data storage layer DS may be formed of a material layer capable of storing data changed using Fowler-Nordheim tunneling. In an embodiment, the data storage layer DS may be formed of a charge trap insulating layer, be formed of a floating gate layer, or be formed of an insulating layer including a conductive nano dot. The charge trap insulating layer may include a silicon nitride layer. The blocking insulating layer BI may extend along an outer wall of the data storage layer DS. The blocking insulating layer BI may include one or more of a silicon dioxide layer (SiO₂) and a high dielectric layer having a dielectric constant higher than a dielectric constant of the silicon dioxide layer. The high dielectric layer may include an aluminum oxide layer, a hafnium oxide layer, and the like.

Referring to FIGS. 3 and 4C, each of the source select gate layer CDL11, the cell gate layer CDL21, and the drain select gate layer CDL31 may surround the plurality of cell pillar structures CPS among the plurality of pillar structures PS. The drain select gate layer CDL31 may be isolated to drain select lines by the select isolation structure SS such that the drain select lines disposed in the same layer may surround different cell pillar structures.

Referring to FIGS. 3, 4A, and 4B, the plurality of gate pillar structures GP may penetrate each stack structure ST, ST_A, ST_B or ST_C in the pass transistor array region AAR. The plurality of gate pillar structures GP may extend in the third direction DR3 to penetrate the plurality of active layers ACT1, ACT2, and ACT3. Each gate pillar structure GP may include a pass gate GE extending in the third direction DR3 to penetrate the plurality of active layers ACT1, ACT2, and ACT3 and a pass gate insulating layer GI surrounding a sidewall of the pass gate GE. The pass gate GE may include various conductive materials such as a doped semiconductor layer and a metal layer. The pass gate GE may further include a metal nitride layer provided as a barrier layer.

A plurality of pass gates GE of the plurality of gate pillar structures GP may be spaced apart from each other in the second direction DR2. The plurality of pass gates GE may be arranged on a plurality of rows. Each pass gate GE may have a cross-sectional structure having a major axis in the first direction DR1 and a minor axis in the second direction DR2 intersecting the plurality of rows. In an embodiment, a cross-section of the pass gate GE may have a rectangular shape having a major axis in the first direction DR1. However, various embodiments of the present disclosure are not limited thereto, and the cross-section of the pass gate GE may be variously designed, such as an elliptical shape.

Each of the plurality of pass gates GE may be used as a gate electrode of a pass transistor corresponding thereto. The plurality of pass gates GE and the plurality of cell level active layers ACT2 may form a pass transistor group including first pass transistors connected to the plurality of cell gate layer CDL21. A sub-active layer configured with the drain select level active layer ACT3 and a pass gate GE may form a second pass transistor connected to a corresponding drain select line among drain select lines configured with the drain select gate layer CDL31. The plurality of pass gates GE and the source select level active layer ACT1 may form a pass transistor group of third pass transistors connected to the source select gate layer CDL11. Because the plurality of active layers ACT1, ACT2, and ACT3 of each stack structure ST, ST_A, ST_B or ST_C surround the pass gate GE, a current flowing path may be provided around each pass gate GE.

The plurality of conductive gate contact structures GC may extend in the third direction DR3 from the plurality pass gates GE, respectively. A cross-section of each conductive gate contact structure GC may be various such as a circular shape, an elliptical shape, and a polygonal shape. The plurality of conductive gate contact structures GC may be disposed on a plurality of rows. Conductive gate contact structures GC of each row may be arranged in a line in the second direction DR2. Conductive gate contact structures GC of different rows may be connected to pass gates GE penetrating different stack structures. For example, a conductive gate contact structure GC of a first row may be connected to a pass gate GE penetrating the stack structure ST_A, and a conductive gate contact structure GC of a second row may be connected to a pass gate GE penetrating the stack structure ST_B.

The conductive gate contact structures GC of each row may be connected to one block select line BSEL. In an embodiment, the block select line BSEL may be connected to conductive gate contact structures GC of a corresponding row via a conductive connection pattern CCP and a conductive via structure VS. The conductive connection pattern CCP may extend in the second direction DR2 to connect the conductive gate contact structures GC of the corresponding row to each other. The conductive connection pattern CCP may be connected to the block select line BSEL corresponding thereto via the conductive via structure VS. However, various embodiments of the present disclosure are not limited thereto. In an embodiment, the conductive gate contact structures GC of each row may be directly connected to the one block select line BSEL corresponding thereto.

The plurality of global conductive patterns GBC may extend in the third direction DR3 from the plurality of second conductive layers CDL12, CDL22, and CDL23. The plurality of global conductive patterns GBC may be used as global line GLL shown in FIG. 1. A global conductive pattern GBC connected to the source select level contact conductive layer CDL12 may serve as the global source select line GSSL shown in FIG. 2A, a global conductive pattern GBC connected to the cell level contact conductive layer CDL22 may serve as the global word line GWL shown in FIG. 2A, and a global conductive pattern GBC connected to a sub-contact conductive layer configured with the drain select level contact conductive layer CDL32 may serve as the global drain select line GDSL shown in FIG. 2A.

The plurality of second conductive layers CDL12, CDL22, and CDL32 may be formed in a stepped structure in the global region GAR. The plurality of global conductive patterns GBC may be connected to a plurality of end portions of the plurality of second conductive layers CDL12, CDL22, and CDL32 forming the stepped structure, respectively.

The semiconductor memory device shown in FIGS. 3, 4A, and 4B may control the source select gate layer CDL11, the plurality of cell gate layers CDL21, and the drain select gate layer CDL31 through pass transistors stacked in a vertical direction, so that, in an embodiment, a planar area allocated to pass transistors may be reduced. The semiconductor memory device shown in FIGS. 3, 4A, and 4B may connect a plurality of active layers ACT1, ACT2, and ACT3 of pass transistors directly to the source select gate layer CDL11, the plurality of cell gate layers CDL21 and the drain select gate layer CDL31 without a separate connection structure.

In embodiments of the present disclosure, which will be described later, detailed descriptions of components overlapping with the components shown in FIGS. 3, 4A, and 4B will be omitted or simplified. In embodiments of the present disclosure, which will be described later, a first direction DR1, a second direction DR2, and a third direction DR3 may be defined as described with reference to FIGS. 3, 4A, and 4B.

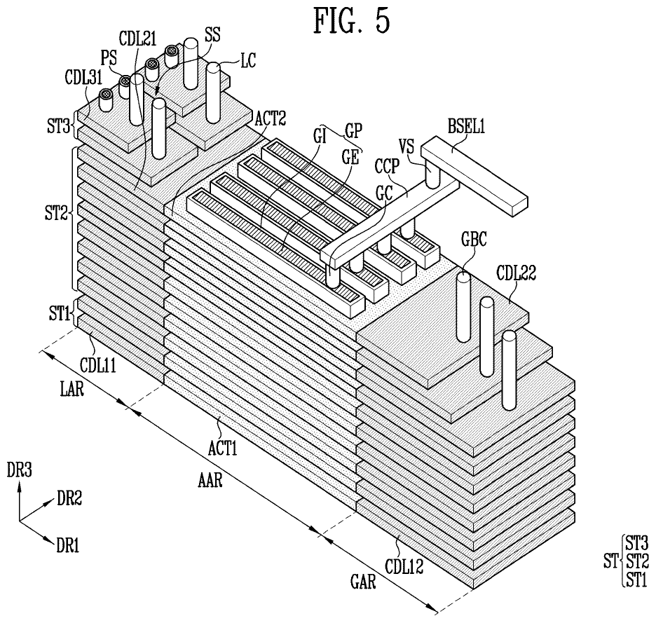

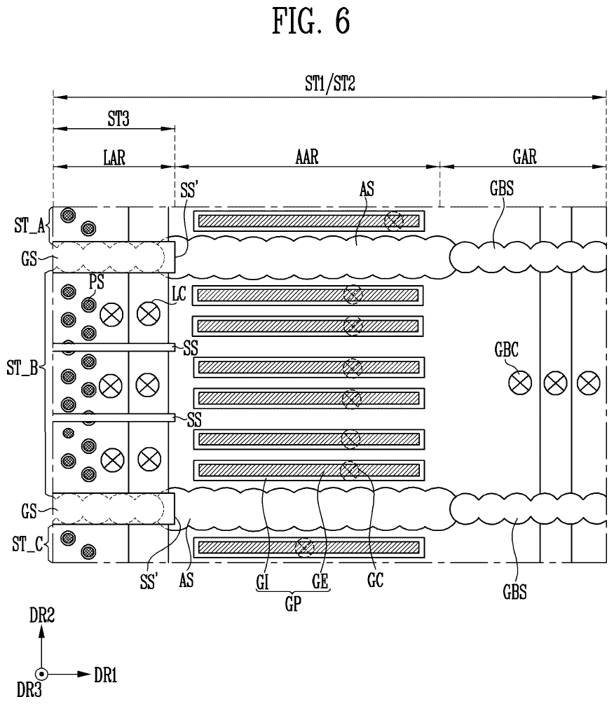

FIGS. 5 and 6 are views illustrating a semiconductor memory device in accordance with an embodiment of the present disclosure.

Referring to FIGS. 5 and 6, a stack structure ST, ST_A, ST_B or ST_C of a memory block may include a local region LAR, a pass transistor array area AAR, and a global area GAR. The stack structure ST, ST_A, ST_B or ST_C may include a plurality of insulating layers and a plurality of horizontal layers CDL11, CDL21, CDL31, ACT1, ACT2, CDL12, and CDL22, which extend in a horizontal direction. The stack structure ST, ST_A, ST_B or ST_C may include a first sub-stack structure ST1, a second sub-stack structure ST2, and a third sub-stack structure ST3, which are stacked in the third direction DR3.

A stack structure ST shown in FIG. 5 may correspond to a portion of each of stack structure ST_A, stack structure ST_B, and stack structure ST_C, which are shown in FIG. 6. The stack structure ST of the semiconductor memory device is illustrated in FIG. 5, and a plan view of the stack structure ST_A, the stack structure ST_B, and the stack structure ST_C, which are spaced apart from each other, is illustrated in FIG. 6.

Referring to FIG. 6, a portion of an edge of each stack structure ST_A, ST_B or ST_C may extend in the first direction DR1 along a sidewall of an isolation group configured with a first isolation structure AS, a second isolation structure GS, and a third isolation structure GBS. The isolation group configured with the first isolation structure AS, the second isolation structure GS, and the third isolation structure GBS may define an edge of the first sub-stack structure ST1 and the second sub-stack structure ST2 of the stack structure ST, ST_A, ST_B or ST_C. A side wall of each of the first isolation structure AS, the second isolation structure GS, and the third isolation structure GBS may include unevenness, and unevenness defined along the sidewalls of the first isolation structure AS, the second isolation structure GS, and the third isolation structure GBS may be formed at the sidewall of each of the first sub-stack structure ST1 and the second sub-stack structure ST2.

Another portion of the edge of each stack structure ST_A, ST_B or ST_C may be defined along a sidewall of a block isolation structure SS′. The block isolation structure SS′ may define an edge of the third sub-stack structure ST3 of each stack structure ST_A, ST_B or ST_C. A side wall of the third sub-stack structure ST3 and the sidewall of the block isolation structure SS′ may extend in the first direction DR1. The block isolation structure SS′ may overlap with the second isolation structure GS.

Referring to FIG. 5, the stack structure ST may include a plurality of horizontal layers CDL11, CDL21, CDL31, ACT1, ACT2, CDL12, and CDL22 extending in the first direction DR1 and the second direction DR2. The plurality of horizontal layers CDL11, CDL21, CDL31, ACT1, ACT2, CDL12, and CDL22 may include a plurality of first conductive layers CDL11, CDL21, and CDL31, a plurality of active layers ACT1 and ACT2, and a plurality of second conductive layers CDL12 and CDL22.

The plurality of first conductive layers CDL11, CDL21, and CDL31 may be disposed in the local region LAR of the stack structure ST to be spaced apart from each other in the third direction DR3. The plurality of first conductive layers CDL11, CDL21, and CDL31 may include at least one source select gate layer CDL11 of the first sub-stack structure ST1, a plurality of cell gate layers CDL21 of the second sub-stack structure ST2, and at least one drain select gate layer CDL31 of the third sub-stack structure ST3. The source select gate layer CDL11 may serve as the source select line SSL shown in FIG. 2B, the plurality of cell gate layers CDL21 may serve as the plurality of word lines WL shown in FIG. 2B, and the drain select gate layer CDL31 may serve as the drain select line DSL shown in FIG. 2B.

The plurality of active layers ACT1 and ACT2 may be disposed in the pass transistor array region AAR of the stack structure ST to be spaced apart from each other in the third direction DR3. The plurality of active layers ACT1 and ACT2 may include at least one source select level active layer ACT1 of the first sub-stack structure ST1 and a plurality of cell level active layers ACT2 of the second sub-stack structure ST2. The source select level active layer ACT1 may be substantially disposed at the same level as the source select gate layer CDL11, be adjacent to the source select gate layer CDL11 in the first direction DR1, and be connected to a sidewall of the source select gate layer CDL11. The plurality of cell level active layers ACT2 may be substantially disposed at the same levels as the plurality of cell gate layers CDL21, may be adjacent to the plurality of cell gate layers CDL21 in the first direction DR1, and may be connected to sidewalls of the plurality of cell gate layers CDL21, respectively.

The plurality of second conductive layers CDL12 and CDL22 may be disposed in the global region GAR of the stack structure ST to be spaced apart from each other in the third direction DR3. The plurality of second conductive layers CDL12 and CDL22 may include at least one source select level contact conductive layer CDL12 of the first sub-stack structure ST1 and a plurality of cell level contact conductive layers CDL22 of the second sub-stack structure ST2. The source select level contact conductive layer CDL12 may be substantially disposed at the same level as the source select gate layer CDL11, and may be spaced apart from the source select gate layer CDL11 in the first direction DR1. The source select level contact conductive layer CDL12 may be adjacent to the source select level active layer ACT1 in the first direction DR1, and may be connected to a sidewall of the source select level active layer ACT1. The plurality of cell level contact conductive layers CDL22 may be substantially disposed at the same levels as the plurality of cell gate layers CDL21, respectively, and may be spaced apart from the plurality of cell gate layers CDL21 in the first direction DR1. The plurality of cell level contact conductive layers CDL22 may be adjacent to the plurality of cell level active layers ACT2 in the first direction DR1, and may be connected to sidewalls of the plurality of cell level active layers ACT2, respectively.

Referring to FIGS. 5 and 6, the third sub-stack structure ST3 may be penetrated by a select isolation structure SS. A depth of the select isolation structure SS may be designed not to penetrate the first sub-stack structure ST1 and the second sub-stack structure ST2. Each drain select gate layer CDL31 in the third sub-stack structure ST3 may be isolated into the drain select lines DSL shown in FIGS. 2A and 2B by the select isolation structure SS.

Each stack structure ST, ST_A, ST_B or ST_C in the local region LAR may be penetrated by a plurality of pillar structures PS. The plurality of pillar structures PS may extend in the third direction DR3 to penetrate the plurality of first conductive layers CDL11, CDL21, and CDL31. As described with reference to FIG. 4C, the plurality of pillar structures PS may include a plurality of cell pillar structures connected to a bit line, and further include dummy cell pillar structures overlapping with the select isolation structure SS. As described with reference to FIG. 4C, each pillar structure PS may include a channel structure and a memory layer.

Referring to FIGS. 5 and 6, a plurality of gate pillar structures GP in the pass transistor array region AAR may penetrate each stack structure ST, ST_A, ST_B or ST_C. The plurality of gate pillar structures GP may extend in the third direction DR3 to penetrate the plurality of active layers ACT1 and ACT2. Each gate pillar structure GP may include a pass gate GE extending in the third direction DR3 to penetrate the plurality of active layers ACT1 and ACT2 and a pass gate insulating layer GI surrounding a sidewall of the pass gate GE.

A plurality of pass gates GE of the plurality of gate pillar structures GP may be spaced apart from each other in the second direction DR2. The plurality of pass gates GE may be arranged on a plurality of rows. Each pass gate GE may have a cross-sectional structure having a major axis in the first direction DR1 and a minor axis in the second direction DR1 intersecting the plurality of rows.

Each of the plurality of pass gates GE may serve as a gate electrode of a pass transistor corresponding thereto. A pass transistor group including the first pass transistors PT1 shown in FIG. 2B may be configured with the plurality of pass gates GE and the plurality of cell level active layers ACT2. The third pass transistor PT3 shown in FIG. 2B may be configured with the plurality of pass gate GE and the source select level active layer ACT1.

A plurality of conductive gate contact structures GC may extend in the third direction DR3 from the plurality of pass gates GE, respectively. The plurality of conductive gate contact structure GC may be disposed on a plurality of rows. Conductive gate contact structures GC of each row may be connected to one first block select line BSEL1. In an embodiment, a first block select line BSEL1 may be connected to conductive gate contact structures GC of a corresponding row via a conductive connection pattern CCP and a conductive via structure VS. The conductive connection pattern CCP may extend in the second direction DR2 to connect conductive gate contact structures GC of a corresponding row. The conductive connection pattern CCP may be connected to a first block select line BSEL1 corresponding thereto via the conductive via structure VS.

A plurality of global conductive patterns GBC may extend in the third direction DR3 from the plurality of second conductive layers CDL12 and CDL22. The plurality of global conductive patterns GBC may include a global conductive pattern connected to the source select level contact conductive layer CDL12 to serve as the global source select line GSSL shown in FIG. 2B and a global conductive pattern connected to the cell level contact conductive layer CDL22 to serve as the global word line GWL shown in FIG. 2B.

The plurality of second conductive layers CDL12 and CDL22 may be disposed in a stepped structure in the global region GAR. The plurality of global conductive patterns GBC may be connected to a plurality of end portions of the plurality of second conductive layers CDL12 and CDL22 forming the stepped structure.

The third sub-stack structure ST3 might not overlap with the pass transistor array region AAR and the global region GAR of the stack structure ST, ST_A, ST_B or ST_C, not to block the plurality of active layers ACT1 and ACT2 and the plurality of second conductive layers CDL12 and CDL22. Drain select lines which are configured with the drain select gate layer CDL31 of the third sub-stack structure ST3 and is isolated by the select isolation structure SS may be connected to conductive local contact structures LC, respectively. Each conductive local contact structure LC may extend in the third direction DR3 from the drain select gate layer CDL31 forming a drain select line corresponding thereto. The plurality of conductive gate contact structures GC may be disposed between the conductive local contact structure LC and the plurality of global conductive patterns GBC.

Although not shown in the drawings, the second block select line BSEL2, the second pass transistor PT2, and the global drain select line GDSL, which are shown in FIG. 2B, may be provided in a structure disposed at a level separate from a level of each stack structure ST, ST_A, ST_B or ST_C including the third sub-stack structure ST3.

The semiconductor memory device shown in FIGS. 5 and 6 may control the source select gate layer CDL11 and the plurality of cell gate layers CDL21 through pass transistors stacked in a vertical direction, so that, in an embodiment, a planar area allocated to the pass transistors may be reduced. The semiconductor memory device shown in FIGS. 5 and 6 may connect a plurality of active layers ACT1 and ACT2 of pass transistors directly to the source select gate layer CDL11 and the plurality of cell gate layers CDL21 without a separate connection structure.

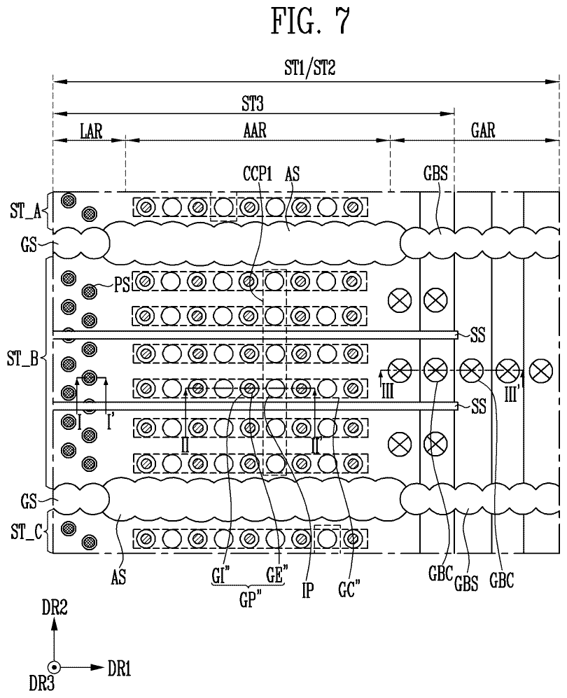

FIG. 7 is a plan view illustrating a semiconductor memory device in accordance with an embodiment of the present disclosure.

Referring to FIG. 7, a memory block of the semiconductor memory device may include a stack structure ST_A, ST_B or ST_C, a plurality of pillar structures PS, a plurality of gate pillar structures GP″, and a plurality of insulative pillar structures IP, which penetrate the stack structure ST_A, ST_B or ST_C, a plurality of conductive gate contact structures GC″, and a plurality of global conductive patterns GBC.

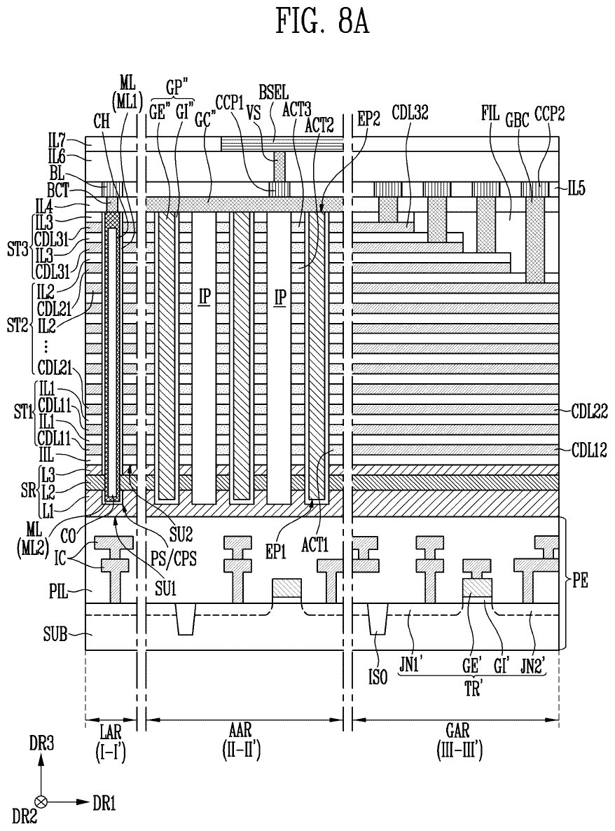

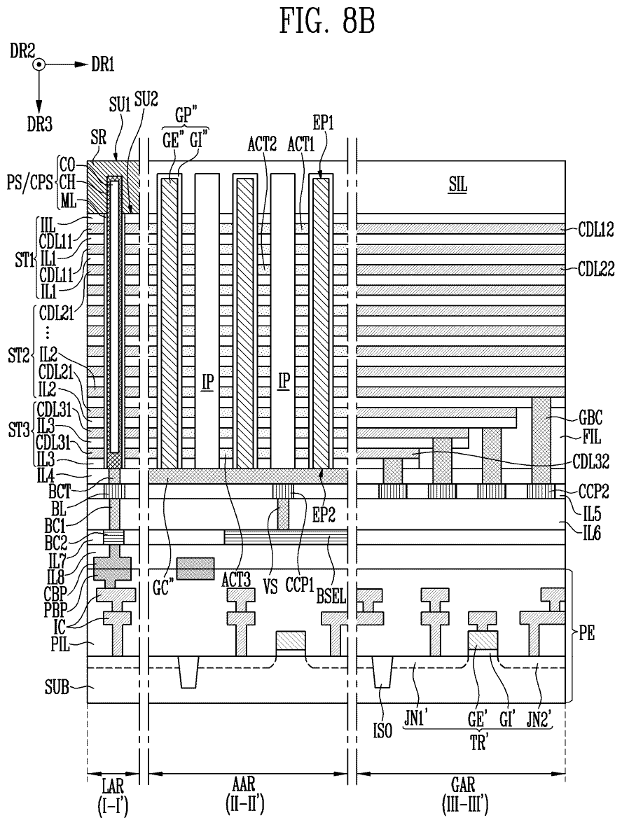

FIGS. 8A and 8B are sectional views illustrating a semiconductor memory device in accordance with an embodiment of the present disclosure. Each of FIGS. 8A and 8B illustrates sectional views of the semiconductor memory device, taken along lines I-I′, II-II′, and III-III′ shown in FIG. 7.

Referring to FIGS. 7, 8A, and 8B, the stack structure ST_A, ST_B or ST_C may overlap with a source layer SR with an interposition insulating layer IIL interposed therebetween. The source layer SR may include a first surface SU1 and a second surface SU2, which face in directions opposite to each other and extend in a horizontal direction. A bit line BL of the semiconductor memory device may be disposed to be spaced apart from the second surface SU2 of the source layer SR in the third direction DR3. The interposition insulating layer IIL and the stack structure ST_A, ST_B or ST_C may be disposed at a level between the second surface SU2 of the source layer SR and the bit line BL.

The source layer SR may include at least one doped semiconductor layer. The source layer SR may include an n-type impurity as a majority carrier. A region including the n-type impurity as the majority carrier may be provided as a source region.

Referring to FIG. 8A, in an embodiment, the source layer SR may include a first doped semiconductor layer L1, a second doped semiconductor layer L2, and a third doped semiconductor layer L3. One of the first doped semiconductor layer L1, the second doped semiconductor layer L2, and the third doped semiconductor layer L3 may include the n-type as the majority carrier, and the others of the first doped semiconductor layer L1, the second doped semiconductor layer L2, and the third doped semiconductor layer L3 may include the n-type impurity of a p-type impurity as the majority carrier. In an embodiment, the second doped semiconductor layer L2 may include the n-type impurity as the majority carrier, and be provided as a source region. The third doped semiconductor layer L3 may include the n-type impurity as the majority carrier or include the p-type impurity as the majority carrier. In accordance with an embodiment in which the third doped semiconductor layer L3 includes the p-type impurity as the majority carrier, the third doped semiconductor layer L3 may be provided as a well region. The first doped semiconductor layer L1 may include the n-type impurity or the p-type impurity as the majority carrier.

Referring to FIG. 8B, in an embodiment, the source layer SR may be formed as a single doped semiconductor layer. The single doped semiconductor layer may include a first conductivity type doped region including the n-type impurity as the majority carrier. The single doped semiconductor layer may further include a second conductivity type doped region including the p-type impurity as the majority carrier.

Referring to FIGS. 7, 8A, and 8B, the stack structure ST_A, ST_B or STC may include a plurality of insulating layers IL1, IL2, and IL3 and a plurality of horizontal layers CDL11, CDL21, CDL31, ACT1, ACT2, ACT3, CDL12, CDL22, and CDL32, which extend in the first direction DR1 and the second direction DR2.

The plurality of insulating layers IL1, IL2, and IL3 may be spaced apart from each other in the third direction DR3 between the second surface SU2 of the source layer SR and the bit line BL. The plurality of insulating layers IL1, IL2, and IL3 may include a local region LAR, a pass transistor array region AAR, and a global region GAR.

The plurality of horizontal layers CDL11, CDL21, CDL31, ACT1, ACT2, ACT3, CDL12, CDL22, and CDL32 may include a plurality of first conductive layers CDL11, CDL21, and CDL31, a plurality of active layers ACT1, ACT2, and ACT3, and a plurality of second conductive layers CDL12, CDL22, and CDL32. In the local region LAR, the plurality of insulating layers IL1, IL2, and IL3 may be alternately disposed one by one with the plurality of first conductive layers CDL11, CDL21, and CDL31 in the third direction DR3. In the pass transistor array region AAR, the plurality of insulating layers IL1, IL2, and IL3 may be alternately disposed one by one with the plurality of active layers ACT1, ACT2, and ACT3 in the third direction DR3. In the global region GAR, the plurality of insulating layers IL1, IL2, and IL3 may be alternately disposed one by one with the plurality of second conductive layers CDL12, CDL22, and CDL32 in the third direction DR3.

The stack structure ST_A, ST_B or ST_C may include a first sub-stack structure ST1, a second sub-stack structure ST2, and a third sub-stack structure ST3, which are stacked in the third direction DR3. The plurality of insulating layers IL1, IL2, and IL3 may include at least one first insulating layer IL1 of the first sub-stack structure ST1, a plurality of second insulating layers IL2 of the second sub-stack structure ST2, and at least one third insulating layer IL3 of the third sub-stack structure ST3. The plurality of first conductive layers CDL11, CDL21, and CDL31 may include at least one source select gate layer CDL11 of the first sub-stack structure ST1, a plurality of cell gate layers CDL21 of the second sub-stack structure ST2, and at least one drain select gate layer CDL31 of the third sub-stack structure ST3. The source select gate layer CDL11 may serve as the source select line SSL shown in FIG. 2A, the plurality of cell gate layer CDL21 may serve as the plurality of word lines WL shown in FIG. 2A, and the drain select gate layer CDL31 may serve as the drain select lien DSL shown in FIG. 2A. The plurality of active layers ACT1, ACT2, and ACT3 may include at least one source select level active layer ACT1 of the first sub-stack structure ST1, a plurality of cell level active layers ACT2 of the second sub-stack structure ST2, and at least one drain select level active layer ACT3 of the third sub-stack structure ST3. The plurality of second conductive layers CDL12, CDL22, and CDL32 may include at least one source select level contact conductive layer CDL12 of the first sub-stack structure ST1, a plurality of cell level contact conductive layers CDL22 of the second sub-stack structure ST2, and at least one drain select level contact conductive layer CDL32 of the third sub-stack structure ST3.

The interposition insulating layer IIL and the plurality of insulating layers IL1, IL2, and IL3 may be penetrated by first isolation structures AS, second isolation structures GS, and third isolation structures GBS. The first isolation structures AS may penetrate the interposition insulating layer IIL and the plurality of insulating layers IL1, IL2, and IL3 in the pass transistor array region AAR, and may be spaced apart from each other in the second direction DR2 with the plurality of active layers ACT1, ACT2, and ACT3 interposed therebetween. The second isolation structures GS may penetrate the interposition insulating layer IIL and the plurality of insulating layers IL1, IL2, and IL3 in the local region LAR, and may be spaced apart from each other in the second direction DR2 with the plurality of first conductive layers CDL11, CDL21, and CDL31 interposed therebetween. The second isolation structures GS may be connected to the first isolation structures AS, respectively. The third isolation structures GBS may penetrate the interposition insulating layer IIL and the plurality of insulating layers IL1, IL2, and IL3 in the global region GAR, and may be spaced apart from each other in the second direction DR2 with the plurality of second conductive layers CDL12, CDL22, and CDL32 interposed therebetween. The third isolation structures GBS may be connected to the first isolation structures AS, respectively.

A first isolation structure AS, a second isolation structure GS, and a third isolation structure GBS, which are arranged in a line in the first direction DR1, may form an isolation group. A sidewall of each of the interposition insulating layer IIL and the plurality of insulating layers IL1, IL2, and IL3 may be defined along sidewalls of the first isolation structure AS, the second isolation structure GS, and the third isolation structure GBS of the isolation group. The sidewall of each of the first isolation structure AS, the second isolation structure GS, and the third isolation structure GBS may include unevenness. Unevenness defined along the sidewalls of the first isolation structure AS, the second isolation structure GS, and the third isolation structure GBS may be formed at the sidewall of each of the interposition insulating layer IIL and the plurality of insulating layers IL1, IL2, and IL3.

The third sub-stack structure ST3 may be penetrated by a select isolation structure SS. A depth of the select isolation structure SS may be designed not to penetrate the first sub-stack structure ST1 and the second sub-stack structure ST2. Each drain select gate layer CDL31 in the third sub-stack structure ST3 may be isolated into the drain select lines DSL shown in FIG. 2A by the select isolation structure SS. The select isolation structure SS may extend in the first direction DR1 to penetrate the drain select level active layer ACT3 and the drain select level contact conductive layer CDL32. Accordingly, the drain select level active layer ACT3 may be isolated into sub-active layers respectively corresponding to the drain select lines by the select isolation structure SS, and the drain select level contact conductive layer CDL32 may be isolated into sub-contact conductive layers respectively corresponding to the drain select lines by the select isolation structure SS.

A plurality of pillar structures PS may extend in the third direction DR3 to penetrate the interposition insulating layer IIL, the plurality of insulating layers IL1, IL2, and IL3, and the plurality of first conductive layers CDL11, CDL21, and CDL31. The plurality of pillar structures PS may be disposed between the second isolation structures GS. As described with reference to FIG. 4C, the plurality of pillar structures PS may include a plurality of cell pillar structures CPS connected to the bit line BL, and further include dummy cell pillar structures overlapping with the select isolation structure SS. As described with reference to FIG. 4C, each pillar structure PS may include a channel structure CH and a memory layer ML. The channel structure CH may be a tubular structure having a length extending in the third direction DR3. A core insulating layer CO may be disposed in a central region defined by the tubular structure of the channel structure CH. The channel structure CH may include a capping portion. The capping portion of the channel structure CH may form one end of the channel structure CH, which faces in the third direction DR3. The capping portion of the channel structure CH may surround an end portion of the core insulating layer CO, which faces the bit line BL, and may include one or more of an n-type impurity and a p-type impurity. In an embodiment, the capping portion of the channel structure may include the n-type impurity as a majority carrier.

The memory layer ML may extend along a sidewall of the channel structure CH. The memory layer ML may be disposed between the channel structure CH and the interposition insulating layer IIL. The memory layer ML may extend in the third direction DR3 to be interposed between each of the first sub-stack structure ST1, the second sub-stack structure ST2, and the third sub-stack structure ST3 and the channel structure CH.

The channel structure CH may include a contact surface in contact with the source layer SR. The contact surface may be defined at a portion of the sidewall of the channel structure CH, the other end of the channel structure CH, and the like. The other end of the channel structure CH may face in a direction opposite to the direction in which the above-described capping portion faces.

Referring to FIG. 8A, in an embodiment, the memory layer ML may be penetrated by the second doped semiconductor layer L2 of the source layer SR, and be isolated into a first memory layer ML1 and a second memory layer ML2. The second doped semiconductor layer L2 of the source layer SR may be in contact with a portion of the sidewall of the channel structure CH. Accordingly, a contact surface between the channel structure CH and the source layer SR may be defined. The first memory layer ML1 may be interposed between each of the first sub-stack structure ST1, the second sub-stack structure ST2, and the third sub-stack structure ST3 and the channel structure CH, and extend between the third doped semiconductor layer L3 of the source layer SR and the channel structure CH. The second memory layer ML2 may be interposed between the first doped semiconductor layer L1 of the source layer SR and the channel structure CH.

Referring to FIG. 8B, in an embodiment, the source layer SR may include a groove. The other end of the channel structure CH may protrude inwardly of the source layer SR as compared with the memory layer ML, and be inserted into the groove of the source layer SR. A contact surface between the channel structure CH and the source layer SR may be defined along the groove of the source layer SR.

Referring to FIGS. 7, 8A, and 8B, each of the plurality of gate pillar structures GP″ may include a pass gate GE″ and a pass gate insulating layer GI″ surrounding a sidewall of the pass gate GE″. A plurality of pass gates GE″ of the plurality of gate pillar structures GP″ may extend in the third direction DR3 to penetrate the interposition insulating layer IIL, the plurality of insulating layers IL1, IL2, and IL3, and the plurality of active layers ACT1, ACT2, and ACT3. Each pass gate GE″ may include a first end portion EP1 facing in the same direction as the first surface SU1 of the source layer SR and a second end portion EP2 facing in the same direction as the second surface SU2 of the source layer SR.

The plurality of gate pillars GP″ may be provided using a process of forming the plurality of pillar structures PS. Accordingly, similarly to the plurality of pillar structures PS, the plurality of gate pillars GP″ may extend at a level between the first surface SU1 and the second surface SU2 of the source layer SR while penetrating the interposition insulating layer IIL. As a result, the first end portion EP1 of the pass gate GE″ may be disposed closer to the plurality of insulating layers IL1, IL2, and IL3 than the first surface SU1 of the source layer SR.

Referring to FIG. 8A, in an embodiment, the source layer SR may extend to overlap with the plurality of active layers ACT1, ACT2, and ACT3. Each pillar structure PS and the pass gate GE″ may extend to the inside of the source layer SR while penetrating the second surface SU2 of the source layer SR, and be formed to a depth to which the pillar structure PS and the pass gate GE″ do not penetrate the first surface SU1 of the source layer SR.

Referring to FIG. 8B, in an embodiment, the source layer SR may be penetrated by a source level insulating layer SIL. The source level insulating layer SIL may extend to overlap with the plurality of active layers ACT1, ACT2, and ACT3 and the plurality of second conductive layers CDL12, CDL22, and CDL32. Each pillar structure PS and the pass gate GE″ may extend to the inside of the source level insulating layer SIL.

Referring to FIGS. 7, 8A, and 8B, the plurality of pass gates GE″ may be spaced apart from each other in the first direction DR1 and the second direction DR2. The plurality of pass gates GE″ and the plurality of insulative pillar structures IP may be arranged on a plurality of rows and a plurality of columns. Two or more pass gates GE″ may be arranged in a line in the first direction DR1 on each row, and two or more pass gates GE″ may be arranged in a line in the second direction DR2 on each column. The plurality of insulative pillar structures IP may be alternately disposed one by one in the first direction DR1 and the second direction DR2 with the plurality of pass gates GE″. A cross-section of each pass gate GE″ and each insulative pillar structure IP may be variously designed, such as a circular shape, an elliptical shape, a square shape, and a rectangular shape.

The plurality of insulating layers IL1, IL2, and IL3 and the plurality of second conductive layers CDL12, CDL22, and CDL32 may be formed in a stepped structure in the global region GAR. The stepped structure may be covered with a filling insulating layer FIL.

The filling insulating layer FIL and the third sub-stack structure ST3 may be covered with a fourth insulating layer IL4. The fourth insulating layer IL4 may be penetrated by a conductive bit line contact structure BCT, a plurality of conductive gate contact structures GC″, and a plurality of global conductive patterns GBC.

The conductive bit line contact structure BCT may be disposed between the bit line BL and the cell pillar structure CPS, to connect the bit line BL and the cell pillar structure CPS to each other.

The plurality of conductive gate contact structures GC″ may correspond to the plurality of rows configured with the plurality of pass gates GE″, respectively. Each conductive gate contact structure GC″ may extend in the first direction DR1 to be connected to pass gates GE″ of a row corresponding thereto.

The plurality of global conductive patterns GBC may penetrate one corresponding insulating layer among the plurality of insulating layers IL1, IL2, and IL3 and the filling insulating layer FIL to be respectively connected to the plurality of second conductive layers CDL12, CDL22, and CDL32.

The bit line BL may be disposed inside a fifth insulating layer IL5. The fifth insulating layer IL5 may extend to cover the fourth insulating layer IL4 and the plurality of conductive gate contact structures GC″. The fifth insulating layer IL5 may be penetrated by a first conductive connection pattern CCP1 and a plurality of second conductive connection patterns CCP2 in addition to the bit line BL. The first conductive connection pattern CCP1 may extend in the second direction DR2 to be connected to conductive gate contact structures GC″ adjacent to each other in the second direction DR2. The plurality of second conductive connection patterns CCP2 may be connected to the plurality of conductive gate contact structures GC″, respectively.

The fifth insulating layer IL5, the bit line BL, the first conductive connection pattern CCP1, and the plurality of second conductive connection patterns CCP2 may be covered with a sixth insulating layer IL6. The sixth insulating layer IL6 may be penetrated by a conductive via structure VS. The conductive via structure VS may be connected to the first conductive connection pattern CCP1.

The sixth insulating layer IL6 and the conductive via structure VS may be covered with a seventh insulating layer IL7. A block select line BSEL may be formed inside the seventh insulating layer IL7. The block select line BSEL may be connected to the conductive via structure VS. The block select line BSEL may be commonly connected to the pass gates GE″ of the plurality of rows via the conductive via structure VS, the first conductive connection pattern CCP1, and the plurality of conductive gate contact structures GC″.

The semiconductor memory device may include a peripheral circuit structure PE. The peripheral circuit structure PE may include a plurality of transistors TR′. In an embodiment, the plurality of transistors TR′ may include the transistor of the page buffer 37 shown in FIG. 1. Each transistor TR′ may be disposed in an active region of a semiconductor substrate SUB, which is partitioned by an isolation layer ISO. Each transistor TR′ may include junctions JN1′ and JN2′, a gate insulating layer GI′ and a gate electrode GE′. The junctions JN1′ and JN2′ may be disposed in the active region of the semiconductor substrate SUB to be spaced apart from each other, and the gate insulating layer GI′ and the gate electrode GE′ may be stacked on the active region between the junctions JN1′ and JN2′.

The plurality of transistors TR′ may be covered with a peripheral insulating structure PIL on the semiconductor substrate SUB. A plurality of interconnections IC may be disposed inside the peripheral insulating structure PIL. The plurality of interconnections IC may include one or more of a plurality of conductive line for electrical connection and a plurality of conductive contact structures.

Referring to FIG. 8A, in an embodiment, the peripheral circuit structure PE may be disposed closer to the source layer SR than the bit line BL. The source layer SR may be disposed between the peripheral insulating structure PIL and the first sub-stack structure ST1.

Referring to FIG. 8B, in an embodiment, the peripheral circuit structure PE may be disposed closer to the bit line BL than the source layer SR. The bit line BL may be disposed between the peripheral insulating structure PIL and the third sub-stack structure ST3. The seventh insulating layer IL7 and the block select line BSEL may be disposed between the bit line BL and the peripheral insulating structure PIL, and an eighth insulating layer IL8 may be interposed between the peripheral insulating structure PIL and each of the seventh insulating layer IL7 and the block select line BSEL.

A plurality of cell-side bonding patterns CBP may be disposed inside the eighth insulating layer IL8. A plurality of peripheral circuit-side bonding patterns PBP corresponding to the plurality of cell-side bonding patterns CBP may be disposed inside the peripheral insulating structure PIL. The plurality of cell-side bonding patterns CBP may be bonded to the plurality of peripheral circuit-side bonding patterns PBP.

Some of the plurality of cell-side bonding patterns CBP may be electrically connected to the bit line BL via at least one bit line connection structure. In an embodiment, a first cell-side bonding pattern among the plurality of cell-side bonding patterns CBP may be electrically connected to the bit line BL via a first bit line connection structure BC1 and the second bit line connection structure BC2. The first bit line connection structure BC1 may penetrate the sixth insulating layer IL6, and the second bit line connection structure BC2 may penetrate the seventh insulating layer IL7.

Some of the plurality of peripheral circuit-side bonding patterns PBP may be electrically connected to the transistor of the page buffer via the interconnection IC. The peripheral circuit-side bonding pattern electrically connected to the transistor of the page buffer may be bonded to the first cell-side bonding pattern. Accordingly, the bit line BL may be electrically connected to the page buffer via the first cell-side bonding pattern and the peripheral circuit-side bonding pattern.

The semiconductor memory device shown in FIGS. 7, 8A, and 8B may control the source select gate layer CDL11, the plurality of cell gate layers CDL21, and the drain select gate layer CDL31 through pass transistors stacked in a vertical direction, so that, in an embodiment, a planar area allocated to the pass transistors may be reduced. The semiconductor memory device shown in FIGS. 7, 8A, and 8B may connect a plurality of active layers ACT1, ACT2, and ACT3 of pass transistors directly to the source select gate layer CDL11, the plurality of cell gate layers CDL21, and the drain select gate layer CDL31 without a separate connection structure.

The peripheral circuit structure PE and the source layer SR, which are shown in FIG. 8A or 8B, may be applied to the semiconductor memory devices shown in FIGS. 3 and 5.

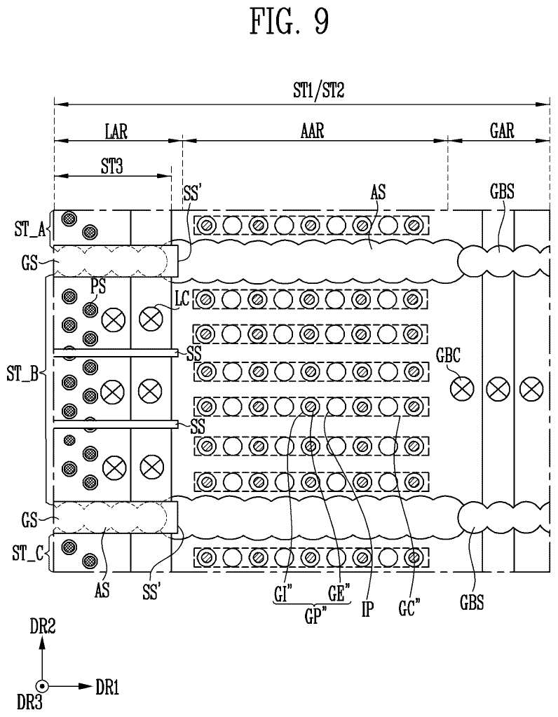

FIG. 9 is a plan view illustrating a semiconductor memory device in accordance with an embodiment of the present disclosure. Referring to FIG. 9, a memory block of the semiconductor

memory device may include a stack structure ST_A, ST_B or ST_C, a plurality of pillar structures PS, a plurality of conductive local contact structures LC, a plurality of gate pillar structures GP″, a plurality of insulative pillar structures IP, a plurality of conductive gate contact structures GC″, and a plurality of global conductive patterns GBC. The semiconductor memory device may include the peripheral circuit structure PE and the source layer SR, which are shown in FIG. 8A or 8B.

The stack structure ST_A, ST_B or ST_C may include a plurality of insulating layers and a plurality of horizontal layers, which extend in the first direction DR1 and the second direction DR2.

The plurality of insulating layers may include a local region LAR, a pass transistor array region AAR, and a global region GAR as described with reference to FIGS. 7, 8A, and 8B. The plurality of insulating layers may include at least one first insulating layer IL1 of a first sub-stack structure ST1, a plurality of second insulating layers IL2 of a second sub-stack structure ST2, and at least one third insulating layer IL3 of a third sub-stack structure ST3 as shown in FIGS. 8A and 8B.

Each of the plurality of horizontal layers may include a plurality of first conductive layers, a plurality of active layers, and a plurality of second conductive layers, which extend in the first direction DR1 and the second direction DR2. As shown in FIGS. 8A and 8B, the plurality of first conductive layers may include at least one source select gate layer CDL11 of the first sub-stack structure ST1, a plurality of cell gate layers CDL21 of the second sub-stack structure ST2, and at least one drain select gate layer CDL31 of the third sub-stack structure ST3. The plurality of active layers may include at least one source select level active layer of the first sub-stack structure ST1 and a plurality of cell level active layers of the second sub-stack structure ST2. As shown in FIGS. 8A and 8B, the source select level active layers ACT1 of the first sub-stack structure ST1 may be adjacent to the source select gate layer CDL11 in the first direction DR1, and may be connected to a sidewall of the source select gate layer CDL11. As shown in FIGS. 8A and 8B, the plurality of cell level active layers ACT2 of the second sub-stack structure ST2 may be adjacent to the plurality of cell gate layers CDL21 in the first direction DR1, and may be connected to sidewalls of the plurality of cell gate layers CDL21, respectively. The plurality of second conductive layers may include at least one source select level contact conductive layer of the first sub-stack structure ST1 and a plurality of cell level contact conductive layers of the second sub-stack structure ST2. As shown in FIGS. 8A and 8B, the source select level contact conductive layer CDL12 of the first sub-stack structure CDL12 may be adjacent to the source select level active layer ACT1 in the first direction DR1, and may be connected to a sidewall of the source select level active layer ACT1. As shown in FIGS. 8A and 8B, the plurality of cell level contact conductive layers CDL22 of the second sub-stack structure ST2 may be adjacent to the plurality of cell level active layers ACT2 in the first direction DR1, and may be connected to sidewalls of the plurality of cell level active layers ACT2, respectively.

Referring to FIG. 9, a portion of an edge of the stack structure ST_A, ST_B or ST_C may extend in the first direction DR1 along a sidewall of an isolation group configured with a first isolation structure AS, a second isolation structure GS, and a third isolation structure GBS. The isolation group configured with the first isolation structure AS, the second isolation structure GS, and the third isolation structure GBS may define an edge of each of the first sub-stack structure ST1 and the second sub-stack structure ST2 of the stack structure ST_A, ST_B or ST_C. A sidewall of each of the first isolation structure AS, the second isolation structure GS, and the third isolation structure GBS may include unevenness, and unevenness defined along the sidewalls of the first isolation structure AS, the second isolation structure GS, and the third isolation structure GBS may be formed at a sidewall of each of the first sub-stack structure ST1 and the second sub-stack structure ST2.

Another portion of the edge of the stack structure ST_A, ST_B or ST_C may be defined along a sidewall of a blocking isolation structure SS′. The block isolation structure SS′ may define an edge of the third sub-stack structure ST3 of each stack structure ST_A, ST_B or ST_C. A sidewall of the third sub-stack structure ST3 and the sidewall of the block isolation structure SS′ may extend in the first direction DR1. The block isolation structure SS′ may overlap with the second isolation structure GS.

Each of the first sub-stack structure ST1 and the second sub-stack structure ST2 may be divided into the local region LAR, the pass transistor array region AAR, and the global region GAR. As shown in FIG. 5, the third sub-stack structure ST3 may overlap with the local region LAR of each of the first sub-stack structure ST1 and the second sub-stack structure ST2, and might not overlap with the pass transistor array region AAR and the global region GAR of each of the first sub-stack structure ST1 and the second sub-stack structure ST2, to open the pass transistor array region AAR and the global region GAR of each of the first sub-stack structure ST1 and the second sub-stack structure ST2.

Referring to FIG. 9, an arrangement and a configuration of the plurality of pillar structure PS may be the same as described with reference to FIGS. 7, 8A, and 8B. An arrangement and a configuration of the plurality of conductive local contact structures LC may be the same as described with reference to FIGS. 5 and 6. Each of the plurality of gate pillar structures GP″ may include a pass gate GE″ and a pass gate insulating layer GI″ surrounding the pass gate GE″. An arrangement and a configuration of each of the plurality of gate pillar structure GP″ and the plurality of insulative pillar structures IP may be the same as described with reference to FIGS. 7, 8A, and 8B. An arrangement and a configuration of each of the plurality of conductive gate contact structures GC″ and the plurality of global conductive patterns GBC may be the same as described with reference to FIGS. 5 and 6.

The semiconductor memory device shown in FIG. 9 may control the source select gate layer of the first sub-stack structure ST1 and the plurality of cell gate layers of the second sub-stack structure ST2 through pass transistors stacked in a vertical direction, so that, in an embodiment, a planar area allocated to the pass transistors may be reduced. The semiconductor memory device shown in FIG. 9 can connect a plurality of active layers of pass transistors connected to the source select gate layer and the plurality of cell gate layers directly to the source select gate layer and the plurality of cell gate layers without a separate connection structure. Referring to FIGS. 3, 4A, 4B, 5, 6, 7, 8A, 8B, and 9, the first to third sub-stack structures ST1, ST2, and ST3 may be formed in a stepped structure in the global region GAR. However, embodiments of the present disclosure are not limited thereto.

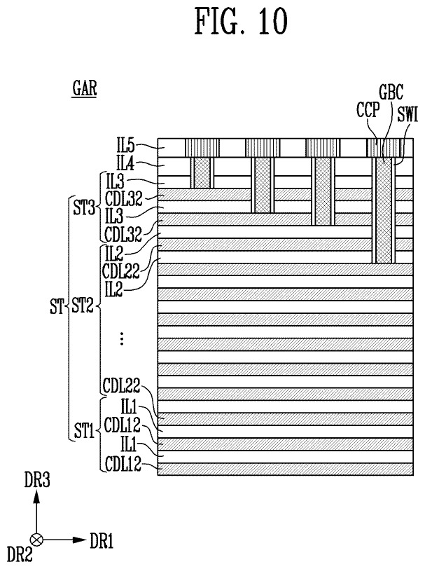

FIG. 10 is a sectional view illustrating a global region of a stack structure in accordance with an embodiment of the present disclosure.

Referring to FIG. 10, a stack structure ST may include a first insulating layer IL1 and a source select level contact conductive layer CDL12 of a first sub-stack structure ST1, a plurality of second insulating layers IL2 and a plurality of cell level contact conductive layers CDL22 of a second sub-stack structure ST2, and a third insulating layer IL3 and a drain select level contact conductive layer CDL33 of a third sub-stack structure ST3. The stack structure ST may be covered with a fourth insulating layer IL4, and the fourth insulating layer IL4 may be covered with a fifth insulating layer IL5.

The first, second, and third insulating layers IL1, IL2, and IL3 of the stack structure ST is not formed in a stepped structure in a global region GAR, but may extend in the first direction DR1 and the second direction DR2 to surround at least one of a plurality of global conductive patterns GBC. The source select level contact conductive layer CDL12, the plurality of cell level contact conductive layers CDL22, and the drain select level contact conductive layer CDL32 of the stack structure ST are not formed in a stepped structure in the global region GAR, but may extend in the first direction DR1 and the second direction DR2 to overlap with the global region GAR of the first, second, and third insulating layers IL1, IL2, and IL3.

Each of the plurality of global conductive patterns GBC may extend in the third direction DR3 to penetrate, from a corresponding conductive layer among the source select level contact conductive layer CDL12, the plurality of cell level contact conductive layers CDL22, and the drain select level contact conductive layer CDL32, an insulating layer above the corresponding conductive layer and a conductive layer above the corresponding conductive layer. A sidewall of each global conductive pattern GBC may be surrounded with a sidewall insulating layer SWI. The sidewall insulating layer SWI may insulate the global conductive pattern GBC and a conductive layer thereabove from each other.

The global conductive pattern GBC and the sidewall insulating layer SWI may extend to penetrate the fourth insulating layer IL4. The global conductive pattern GBC may be connected to a conductive connection pattern CCP inside the fifth insulating layer IL5.

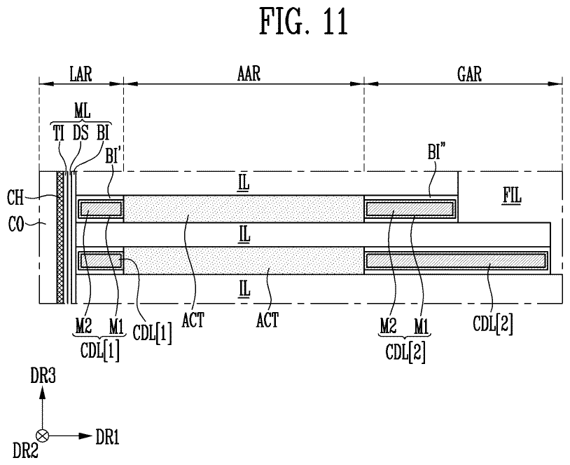

FIG. 11 is a sectional view illustrating a semiconductor memory device in accordance with an embodiment of the present disclosure.

Referring to FIG. 11, each of a first conductive layer CDL[1], an active layer ACT, and a second conductive layer CDL[2]) of the semiconductor memory device in accordance with an embodiment of the present disclosure may extend in the first direction DR1 and the second direction DR2, and may be interposed between insulating layers IL adjacent to each other in the third direction DR3. The first conductive layer CDL[1] may be interposed between the insulating layers IL in a local region LAR, and surround a sidewall of a pillar structure including a core insulating layer CO, a channel structure CH, and a memory layer ML. The second conductive layer CDL[2] may be interposed between the insulating layers IL in a global region GAR, and may be spaced apart from the first conductive layer CDL[1]. The active layer ACT may be interposed between the insulating layers IL in a pass transistor array region AAR, and include one side in contact with the first conductive layer CDL[1] and the other side connected to the second conductive layer CDL[2].

The memory layer ML may include a tunnel insulating layer TI, a data storage layer DS, and a blocking insulating layer BI as described with reference to FIG. 4C. The semiconductor memory device may further include a first blocking insulating layer BI′ and a second blocking insulating layer BI″ in addition to the blocking insulating layer BI of the memory layer ML. The first blocking insulating layer BI′ and the second blocking insulating layer BI″ may include an aluminum oxide layer, a hafnium oxide layer, and the like. The first blocking insulating layer BI′ may be interposed between the insulating layer IL and the first conductive layer CDL[1], and may extend between the blocking insulating layer BI and the first conductive layer CDL[1]. The second blocking insulating layer BI″ may be interposed between the insulating layer IL and the second conductive layer CDL[2]. When the insulating layers IL are formed in a stepped structure in the global region GAR, the semiconductor memory device may include a filling insulating layer FIL covering the stepped structure. The second blocking insulating layer BI″ may extend to be interposed between the filling insulating layer FIL and the second conductive layer CDL[2].

The first conductive layer CDL[1] and the second conductive layer CDL[2] may be formed of the same conductive material. In an embodiment, each of the first conductive layer CDL[1] and the second conductive layer CDL[2] may include a metal material M2 and a metal nitride M1 formed along a surface of the metal material M2.

Hereinafter, a method of manufacturing a semiconductor memory device in accordance with embodiments of the present disclosure will be described mainly with respect to components formed at a level between a source layer and a bit line.

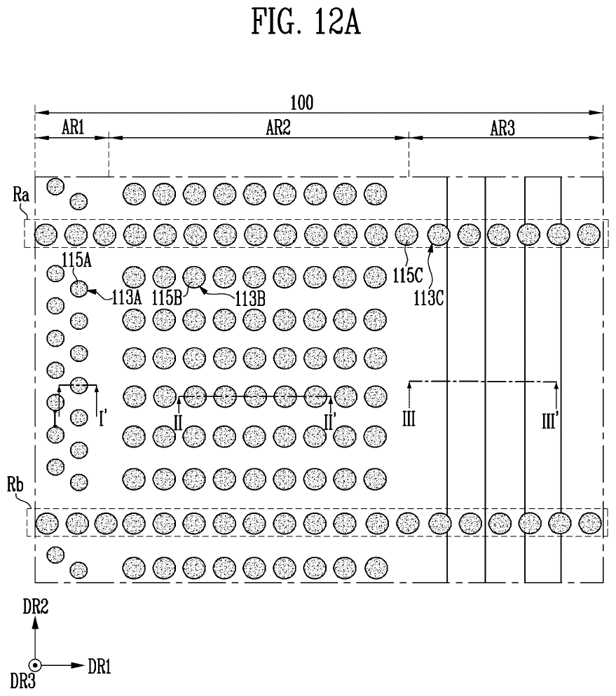

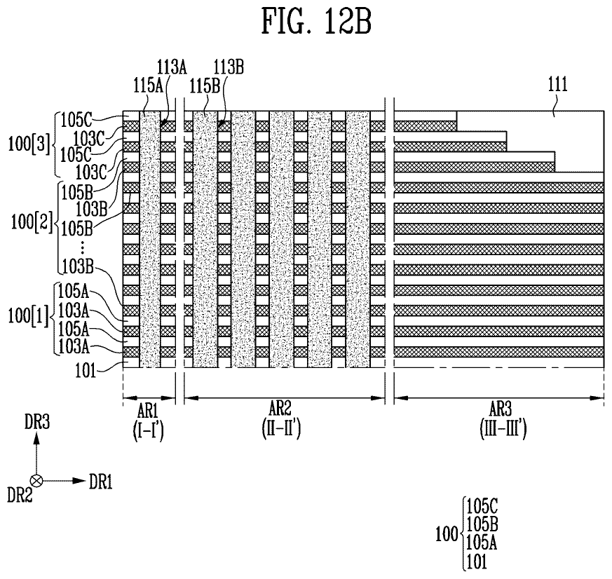

FIGS. 12A, 12B, 13A, 13B, 14A, 14B, 15A, 15B, 16A, 16B, 17A, 17B, 17C, 18, 19, 20A, 20B, 21A, 21B, 21C, 22A, 22B, and 23 are views illustrating a method of manufacturing a semiconductor memory device in accordance with an embodiment of the present disclosure.

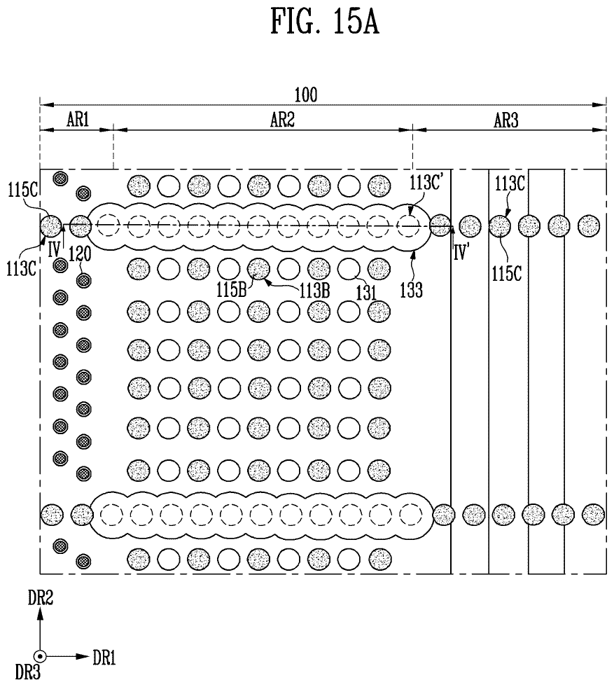

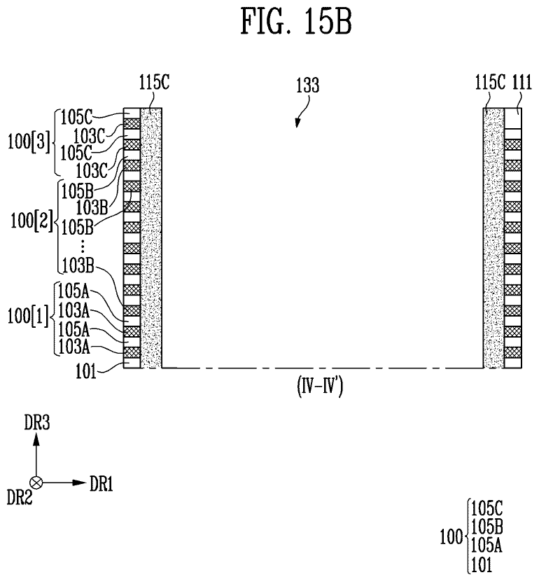

FIGS. 12A, 13A, 14A, 15A, 16A, 17A, 18, 19, 20A, 22A, and 22B are plan views illustrating a method of manufacturing a semiconductor memory device. Each of FIGS. 12B, 13B, 14B, 17B, 20B, 21a, 21B, 21C, and 23 illustrates sectional views of a process result, taken along lines I-I′, II-II′, and III-III′ shown in a corresponding plan view. Each of FIGS. 15B, 16B, and 17C illustrates a sectional view of a process result, taken along line IV-IV′ shown in a corresponding plan view.

FIGS. 12A and 12B are views illustrating processes of forming a mold structure 100 and a plurality of sacrificial pillars 115A, 115B, and 115C.

Referring to FIGS. 12A and 12B, an interposition insulating layer 101 may be formed on a lower structure (not shown). Although not shown in the drawings, in an embodiment, the lower structure may include the peripheral circuit structure PE shown in FIG. 8A, and a preliminary source layer including the first doped semiconductor layer L1, the third doped semiconductor layer L3, which are shown in FIG. 8, and a sacrificial structure between the first doped semiconductor layer L1 and the third doped semiconductor layer L3. The sacrificial structure of the preliminary source layer may be replaced with the second doped semiconductor layer L2 shown in FIG. 8A in a subsequent process. In another embodiment, the lower structure may be a sacrificial substrate formed of a silicon wafer or the like. The sacrificial substrate may be replaced with the source layer SR shown in FIG. 8B.

The interposition insulating layer 101 may include a top surface extending in the first direction DR1 and the second direction DR2. A plurality of sacrificial layers 103A, 103B, and 103C and a plurality of insulating layers 105A, 105B, and 105C may be alternately stacked one by one in the third direction DR3 on the top surface of the interposition insulating layer 101. The plurality of sacrificial layers 103A, 103B, and 103C may be formed of a material having an etch selectivity with respect to the interposition insulating layer 101 and the plurality of insulating layers 105A, 105B, and 105C. In an embodiment, the interposition insulating layer 101 and the plurality of insulating layers 105A, 105B, and 105C may include an insulating material such as a silicon oxide layer or a silicon oxynitride layer, and the plurality of sacrificial layers 103A, 103B, and 103C may include a sacrificial insulating material.

The plurality of sacrificial layers 103A, 103B, and 103C and the plurality of insulating layers 105A, 105B, and 105C may be divided into a first sub-stack structure 100[1], a second sub-stack structure 100[2], and a third sub-stack structure 100[3]. Specifically, the plurality of sacrificial layers may include at least one first sacrificial layer 103A of the first sub-stack structure 100[1], a plurality of second sacrificial layers 103B of the second sub-stack structure 100[2], and at least one third sacrificial layer 103C of the third sub-stack structure 100[3]. The plurality of insulating layers may include a first insulating layer 105A of the first sub-stack structure 100[1], a plurality of second insulating layers 105B of the second sub-stack structure 100[2], and at least one third insulating layer 105C of the third sub-stack structure 100[3]. The interposition insulating layer 101 and the plurality of insulating layers 105A, 105B, and 105C may form a mold structure 100. The mold structure 100 may include a first region AR1, a second region AR2, and a third region AR3. The first region AR1 and the third region AR3 may be spaced apart from each other in a horizontal direction, and the second region AR2 may be disposed between the first region AR1 and the third region AR3. In an embodiment, the first region AR1, the second region AR2, and the third region AR3 may be arranged in a line in the first direction DR1.

Subsequently, a plurality of holes 113A, 113B, and 113C may be formed using the same mask process. The plurality of holes may include a plurality of first holes 113A, a plurality of second holes 113B, and a plurality of third holes 113C. The plurality of first holes 113A may penetrate the first region AR1 of the mold structure 100 and the plurality of sacrificial layers 103A, 103B, and 103C. The plurality of second holes 113B may penetrate the second region AR2 of the mold structure 100 and the plurality of sacrificial layers 103A, 103B, and 103C. In an embodiment, the plurality of second holes 113B may be formed in a structure and an arrangement, which correspond to the plurality of gate pillars GP shown in FIG. 3 or 5. In another embodiment, the plurality of second holes 113B may be formed in a structure and an arrangement, which correspond to the plurality of gate pillar structures GP″ and the plurality of insulative pillar structures IP, which are shown in FIG. 7 or 9. Hereinafter, the method of manufacturing the semiconductor memory device will be described based on an embodiment in which the plurality of second holes 113B are formed in the structure and the arrangement, which correspond to the plurality of gate pillar structures GP″ and the plurality of insulative pillar structures IP, which are shown in FIG. 7 or 9. The plurality of third holes 113C may form a plurality of rows. Third holes 113C on each row may be arranged in a line in the first direction DR1. The third holes 113C on each row may be divided into a first group penetrating the first region AR1 of the mold structure 100 and the plurality of sacrificial layers 103A, 103B, and 103C, a second group penetrating the second region AR2 of the mold structure 100 and the plurality of sacrificial layers 103A, 103B, and 103C, and a third group penetrating the third region AR3 of the mold structure 100 and the plurality of sacrificial layers 103A, 103B, and 103C.

In an embodiment, the plurality of third holes 113C may form a first row Ra and a second row Rb, which are adjacent to each other in the second direction DR2. The plurality of first holes 113A and the plurality of second holes 113B may be disposed between the first row Ra and the second row Rb.

Although not shown in the drawings, the plurality of holes 113A, 113B, and 113C may extend to the inside of the lower structure. In an embodiment, when the lower structure includes the first doped semiconductor layer L1 shown in FIG. 8A and the third doped semiconductor layer L3 shown in FIG. 8A, the plurality of holes 113A, 113B, and 113C may extend to the inside of the first doped semiconductor layer L1 shown in FIG. 8A. In another embodiment, when the lower structure includes the sacrificial substrate, the plurality of holes 113A, 113B, and 113C may extend to the inside of the sacrificial substrate.

After that, a plurality of sacrificial pillars 115A, 115B, and 115C may be formed inside the plurality of holes 113A, 113B, and 113C, respectively. The plurality of sacrificial pillars 115A, 115B, and 115C may include a material having an etch selectivity with respect to the plurality of sacrificial layers 103A, 103B, and 103C. In an embodiment, the plurality of sacrificial layers 103A, 103B, and 103C may include amorphous carbon, tungsten, a titanium nitride layer, and the like. The plurality of sacrificial pillars may include a plurality of first sacrificial pillars 115A inside the plurality of first holes 113A, a plurality of second sacrificial pillars 115B inside the plurality of second holes 113B, and a plurality of third sacrificial pillars 115C inside the plurality of third holes 113C.

Before the plurality of holes 113A, 113B, and 113C are formed or after the plurality of sacrificial pillars 115A, 115B, and 115C are formed, the plurality of sacrificial layers 103A, 103B, and 103C and the plurality of insulating layers 105A, 105B, and 105C may be etched, thereby forming a stepped structure. The stepped structure may be formed in the third region AR3, and be covered with a filling insulating layer 111. The filling insulating layer 111 may be formed of an insulating material such as a silicon oxide layer. However, various embodiments of the present disclosure are not limited thereto, and a process of forming the stepped structure may be omitted.

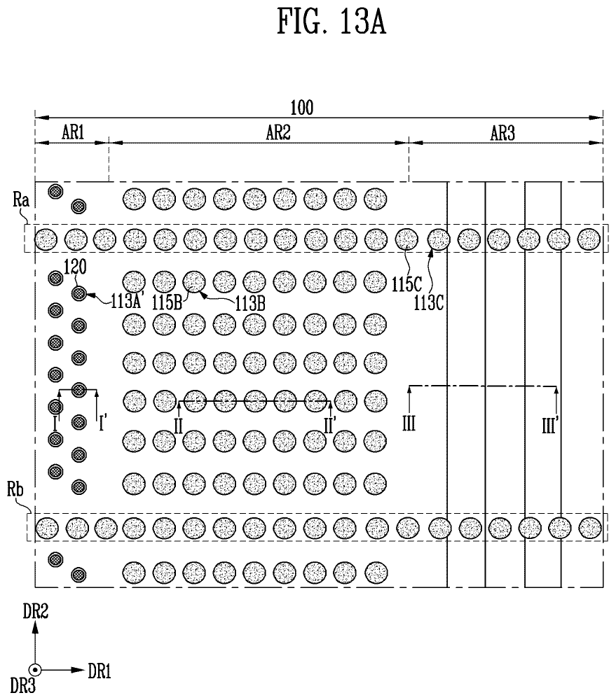

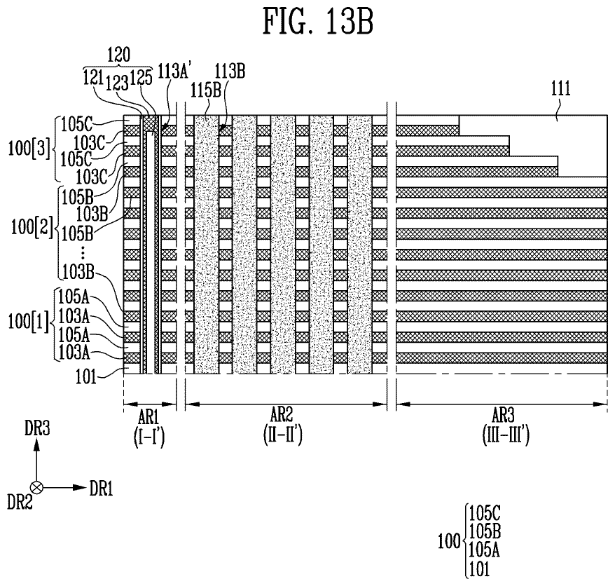

FIGS. 13A and 13B are views illustrating processes of forming a plurality of pillar structures 120.

Referring to FIGS. 13A and 13B, the plurality of first sacrificial pillars 115A shown in FIGS. 12A and 12B may be removed. Accordingly, the plurality of first holes may be opened. “113A” designates the plurality of opened first holes after the first sacrificial pillars 115A are removed. A plurality of pillar structures 120 may be formed inside the plurality of opened first holes 113A′, respectively.

A process of forming the plurality of pillar structure 120 may include a process of forming a memory layer 121 along an inner wall of the first hole 113A′ and a process of forming a channel structure 123 and a core insulating layer 125 in a central region of the first hole 113A′, which is opened by the memory layer 121. The memory layer 121 may include a blocking insulating layer, a data storage layer, and a tunnel insulating layer as described with reference to FIG. 4C.

In an embodiment, the process of forming the channel structure 123 and the core insulating layer 125 may include a process of forming a channel layer along an inner wall of the memory layer 121 and a process of filling a central region having a tubular structure, which is defined by the channel layer, with the core insulating layer 125 and a capping pattern. The channel layer may be formed of a semiconductor material such as silicon (Si), germanium (Ge) or any mixture thereof, which serve as a channel region. The capping pattern may be formed of a doped semiconductor layer. The channel layer and the capping pattern may form the channel structure 123.

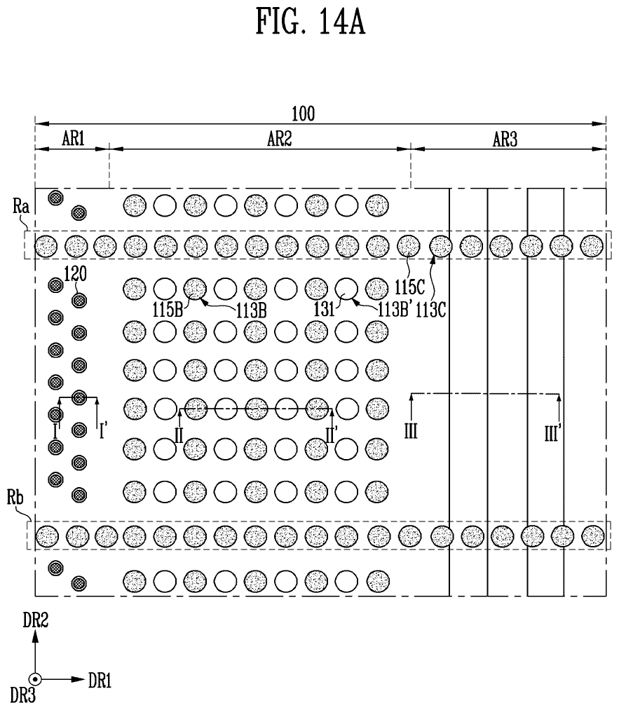

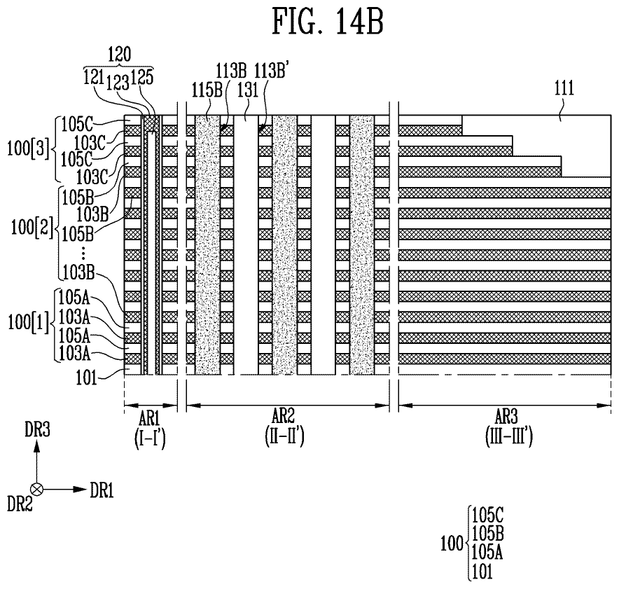

FIGS. 14A and 14B are views illustrating a process of forming insulative pillar structure 131.

Referring to FIGS. 14A and 14B, as some of the plurality of second sacrificial pillars 115B are removed, some of the plurality of second holes may be opened. “113B′” designates the opened second holes. The opened second holes 113B′ may be alternately disposed one by one in the first direction DR1 and the second direction DR2 with the remaining second sacrificial pillars 115B.

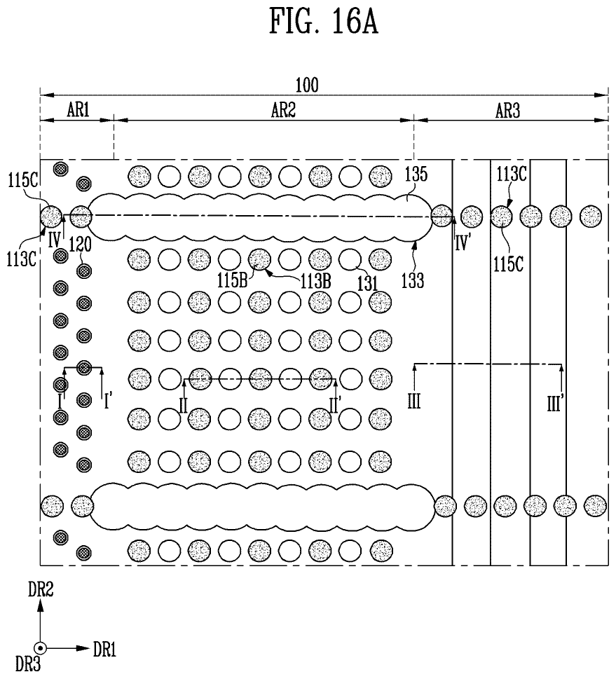

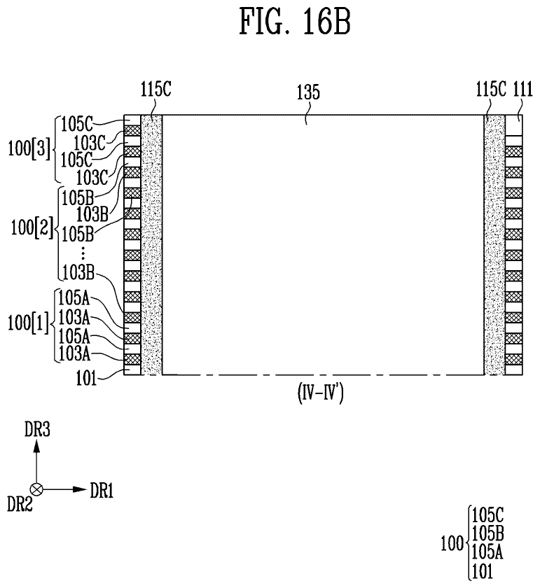

Subsequently, a plurality of insulative pillar structures 131 may be provided by filling the second holes 113B′ with an insulating material. FIGS. 15A, 15B, 16A, and 16B are views illustrating a process of forming first isolation structures 135.

Referring to FIGS. 15A and 15B, some of the plurality of third sacrificial pillars 113C may be removed such that the third holes of the second group are opening on each row. “113C′” designates the opened third holes.

A portion of each of the interposition insulating layer 101, the plurality of sacrificial layers 103A, 103B, and 103C, and the plurality of insulating layers 105A, 105B, and 105C may be etched through the third holes 113C′ of the second group such that the third holes 113C′ of the second group are connected to each other. Accordingly, a first trench 133 may be formed. The first trench 133 may be defined by the third holes 113C′ of the second group, which are connected to each other. The first trench 133 may have unevenness corresponding to a cross-section of each of the third holes 113′ of the second group.

Referring to FIGS. 16A and 16B, the first trench 133 may be filled with a first isolation structure 135. The first isolation structure 135 may be formed of a material different from the material of the plurality of sacrificial layers 103A, 103B, and 130C and the remaining third sacrificial pillars 115C. In an embodiment, the first isolation structure 135 may include an insulating material such as a silicon oxide layer.

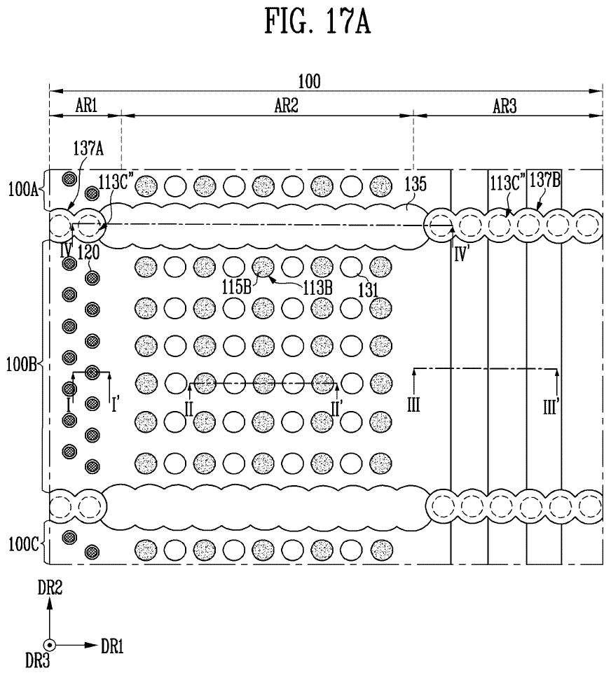

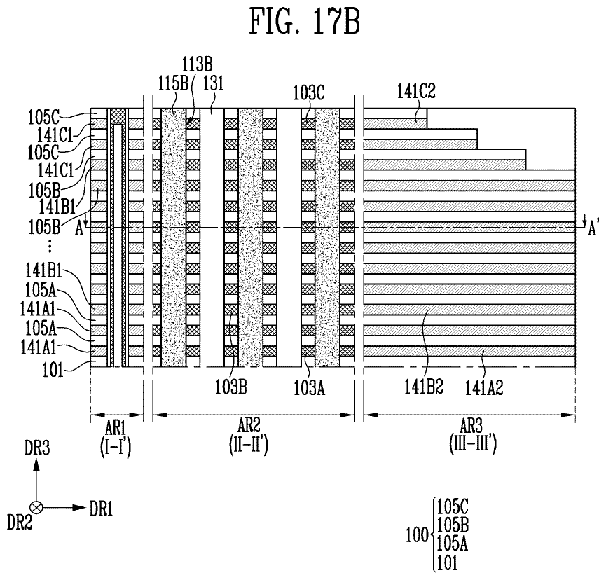

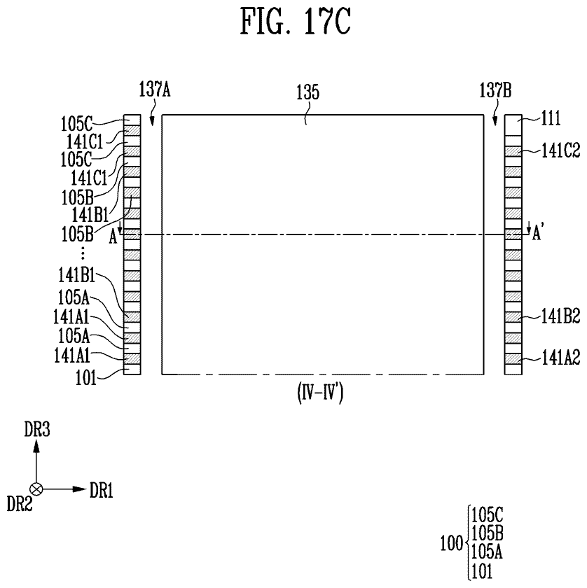

FIGS. 17A, 17B, and 17C are views illustrating a process of isolating preliminary stack structures 100A, 100B, and 100C from each other.

Referring to FIGS. 17A, 17B, and 17C, the remaining third sacrificial pillars 113C may be removed such that the third holes of the first group and the third holes of the third group are opened. “113C″” designates the opened third holes.

A portion of each of the interposition insulating layer 101, the plurality of sacrificial layers 103A, 103B, and 103C, and the plurality of insulating layers 105A, 105B, and 105C may be etched through the third holes 113C″ of each of the first and third groups such that the third holes 113C″ of the first group may be connected to each other and the third holes 113C″ are connected to each other. Accordingly, a second trench 137A and a third trench 137B may be formed. The second trench 137A may be defined by the third holes 113C″ of the first group, which are connected to each other. The third trench 137B may be defined by the third holes 113C″ of the third group, which are connected to each other. Each of the second trench 137A and the third trench 137B may have unevenness corresponding to a cross-section of each of the third holes 113C″. Each of the second trench 137A and the third trench 137B may open the first isolation structure 135, and a portion of the first isolation structure 135 may be etched while each of the second trench 137A and the third trench 137B is formed.

Subsequently, a first portion of the plurality of sacrificial layers 103A, 103B, and 103C overlapping with the first region AR1 of the mold structure 100 and a second portion of the plurality of sacrificial layers 103A, 103B, and 103C overlapping with the third region AR3 of the mold structure 100 may be removed through the second trench 137A and the third trench 137B. Subsequently, a conductive material may be formed inside each of regions in which the first portion and the second portion of the plurality of sacrificial layers 103A, 103B, and 103C are removed. Before the conductive material is formed, the first blocking insulating layer described with reference to FIG. 11 may be formed in the region in which the first portion of the plurality of sacrificial layers 103A, 103B, and 103C is removed, and the second blocking insulating layer described with reference to FIG. 11 may be formed in the region in which the second portion of the plurality of sacrificial layers 103A, 103B, and 103C is removed.

The conductive material formed in the region in which the first portion of the plurality of sacrificial layers 103A, 103B, and 103C is removed may form a plurality of first conductive layers 141A1, 141B1, and 141C1 overlapping with the first region AR1 of the mold structure 100. The conductive material formed in the region in which the second portion of the plurality of sacrificial layers 103A, 103B, and 103C is removed may form a plurality of second conductive layers 141A2, 141B2, and 141C2 overlapping with the third region AR3 of the mold structure 100. The plurality of first conductive layers may include at least one source select gate layer 141A1, a plurality of cell gate layers 141B1, and at least one drain select gate layer 141C1. The plurality of second conductive layers may include at least one source select level contact conductive layer 141A2, a plurality of cell level contact conductive layers 141B2, and at least one drain select level contact conductive layer 141C2.

The mold structure 100 may be isolated into preliminary stack structures 100A, 100B, and 100C by the second trench 137A, the first isolation structure 135, and the third trench 137B, which are connected to each other. Each preliminary stack structure 100A, 100B or 100C may include the plurality of first conductive layers 141A1, 141B1, and 141C1, the plurality of second conductive layers 141A2, 141B2, and 141C2, and the plurality of sacrificial layers 103A, 103B, and 103C between the plurality of first conductive layers 141A1, 141B1, and 141C1 and the plurality of second conductive layers 141A2, 141B2, and 141C2.

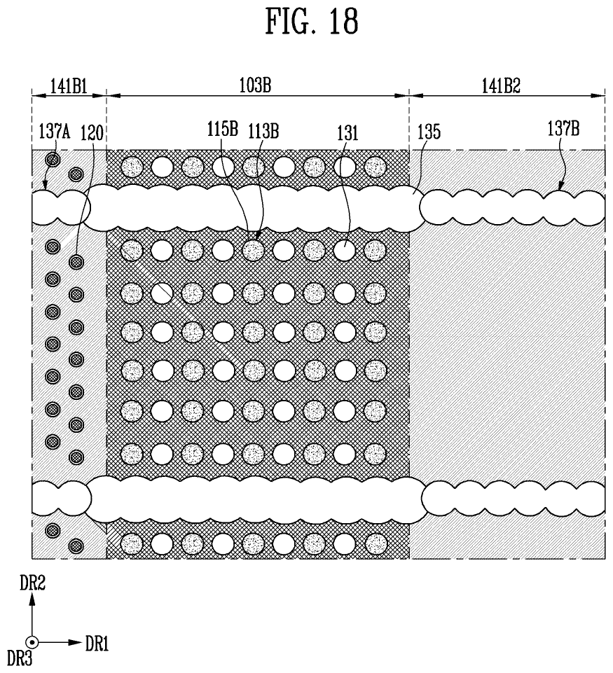

FIG. 18 is a plan view illustrating the cell gate layer 141B1, the second sacrificial layer 103B, and the cell level contact conductive layer 141B2, taken along line A-A′ shown in FIGS. 17B and 17C.

Referring to FIG. 18, the cell gate layer 141B1, the second sacrificial layer 103B, and the cell level contact conductive layer 141B2 may be arranged in the first direction DR1 along the second trench 137A, the first isolation structure 135, and the third trench 137B.

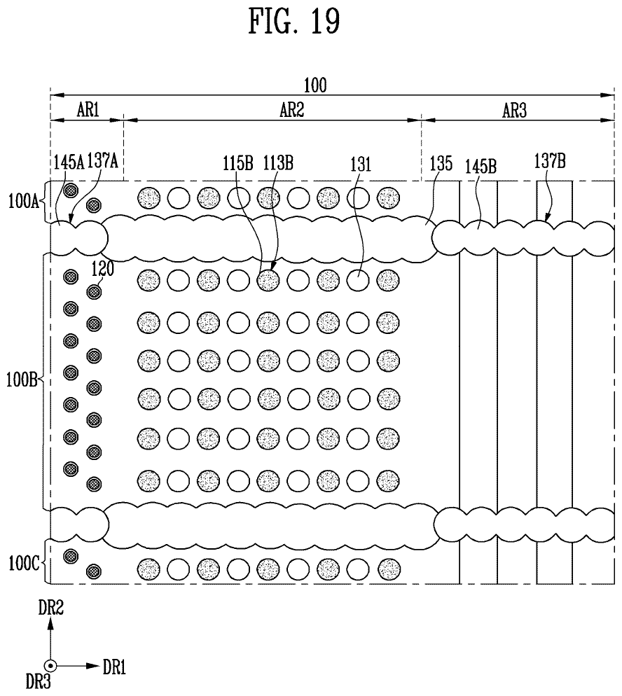

FIG. 19 is a plan view illustrating a process of forming a second isolation structure 145A and a third isolation structure 145B.

Referring to FIG. 19, each of the second trench 137A and the third trench 137B may be filled with at least one of an insulating layer, a conductive layer, and a semiconductor layer. Accordingly, a second isolation structure 145A may be formed inside the second trench 137A, and a third isolation structure 145B may be formed inside the third trench 137B. When each of the second isolation structure 145A and the third isolation structure 145B includes a conductive layer or a semiconductor layer, a spacer insulating layer may be formed on a sidewall of each of the second trench 137A and the third trench 137B before the conductive layer or the semiconductor layer is formed.

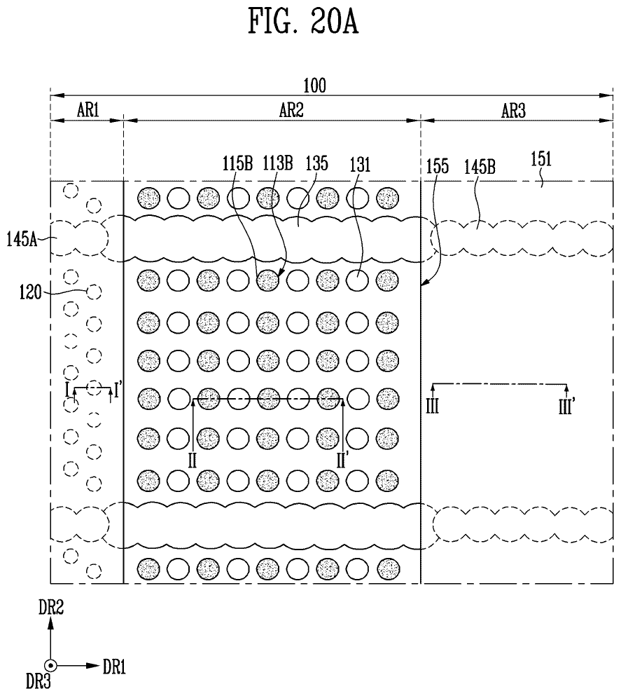

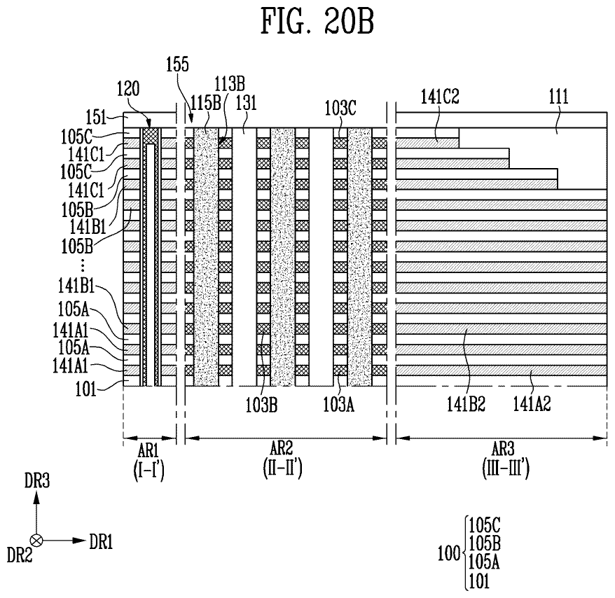

FIGS. 20A and 20B are views illustrating a process of forming a protective layer 151 including an opening 155.

Referring to FIGS. 20A and 20B, a protective layer 151 may be formed to cover the filling insulating layer 111 and the preliminary stack structures 100A, 100B, and 100C shown in FIG. 19. The protective layer 151 may be formed of a material different from the material of the remaining second sacrificial pillars 115B and the plurality of sacrificial layers 103A, 103B, and 103C. In an embodiment, the protective layer 151 may include a silicon oxide layer.

Subsequently, an opening 155 may be formed by etching a portion of the protective layer 151. The opening 155 may overlap with the second region AR2 of the mold structure 100, and open the remaining second sacrificial pillars 115B and the insulative pillar structures 131.

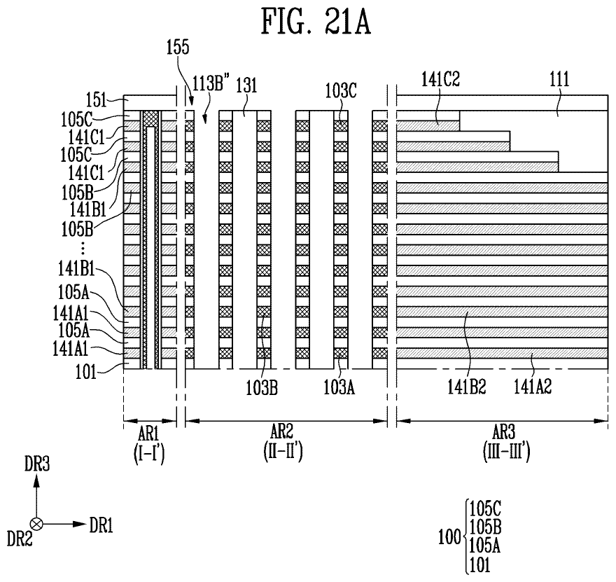

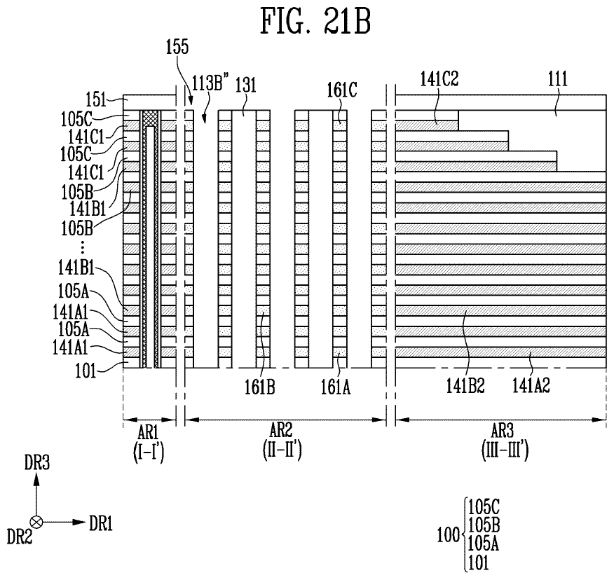

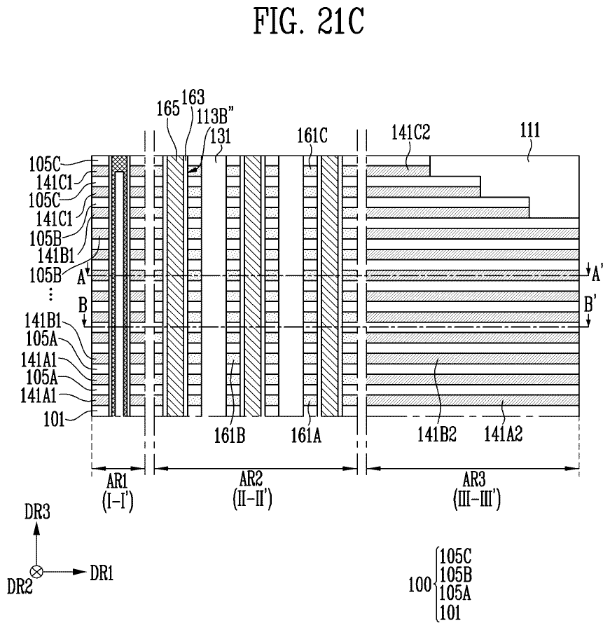

FIGS. 21A, 21B, and 21C are views illustrating a process of forming a plurality of active layers 161A, 161B, and 161C and a process of forming a gate pillar structure.

Referring to FIG. 21A, the remaining second sacrificial pillars 115B shown in FIG. 20B may be removed through the opening 155. Accordingly, the second holes may be opened. “113B″” designates the opened second holes. The second holes 113B″ may be alternately disposed one by one in the first direction DR1 and the second direction DR2 with the insulative pillar structures 131.

Referring to FIG. 21B, after the plurality of sacrificial layers overlapping with the second region AR2 of the mold structure 100 are removed through the second holes 113B″, a plurality of active layers 161A, 161B, and 161C may be formed in regions in which the plurality of sacrificial layers are removed. In an embodiment, the plurality of insulative pillar structures 131 may serve as supports capable of reducing deformation of the structure of the second region AR2 of the mold structure 100.

Although not shown in the drawing, in the case of an embodiment in which a first blocking insulating layer is formed along a surface of each of the plurality of first conductive layers 141A1, 141B1, and 141C1 and a second blocking insulating layer is formed along a surface of each of the plurality of second conductive layers 141A2, 141B2, and 141C2, a portion of each of the first blocking insulating layer and the second blocking insulating layer may be removed through the second holes 113B″ before the plurality of active layers 161A, 161B, and 161C are formed. Accordingly, a sidewall of each of the plurality of first conductive layers 141A1, 141B1, and 141C1 and the plurality of second conductive layers 141A2, 141B2, and 141C2 may be exposed, and may be in contact with the plurality of active layers 161A, 161B, and 161C formed subsequently.

The plurality of active layers 161A, 161B, and 161C may include a source select level active layer 161A, a plurality of cell level active layers 161B, and a drain select level active layer 161C.

Referring to FIG. 21C, a gate pillar structure including a pass gate insulating layer 163 and a pass gate 165 may be formed inside each of the second holes 113B″.

A process of forming the gate pillar structure may include a process of forming the pass gate insulating layer 163 along an inner wall of the second hole 113B″, a process of filling a central region of the second hole 113B″, which is opened by the pass gate insulating layer 163, with a conductive material, and a process of planarizing the conductive material and the pass gate insulating layer 163. The protective layer 151 shown in FIG. 21 may be removed through the planarization process.

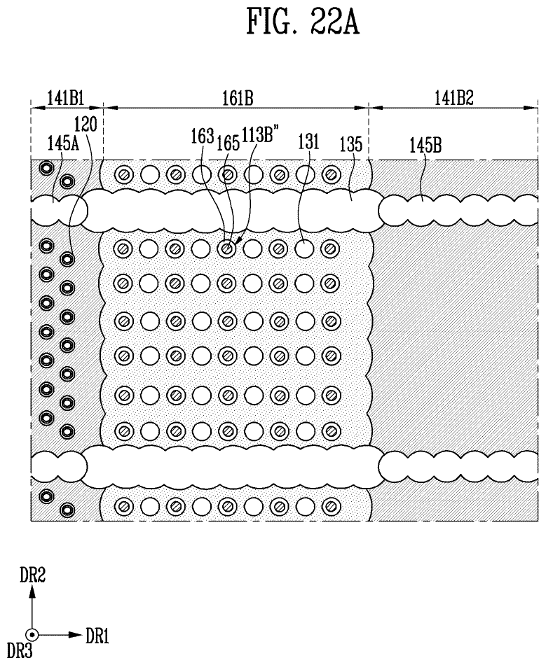

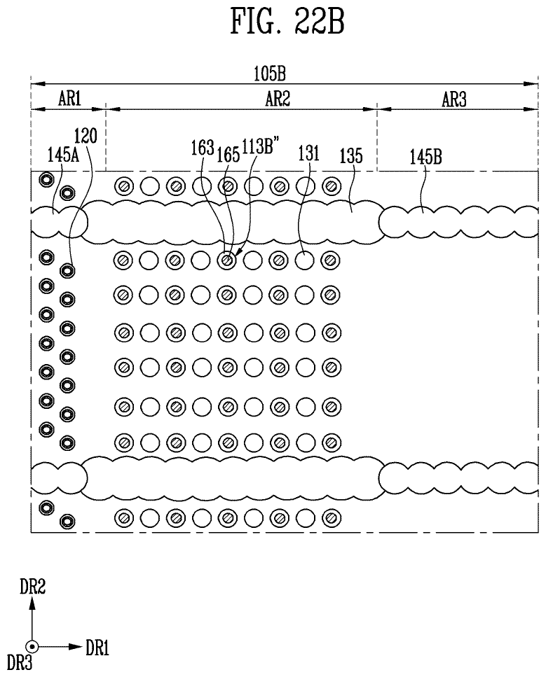

FIG. 22A is a plan view illustrating the cell gate layer 141B1, the cell level active layer 161B, and the cell level contact conductive layer 141B2, taken along line A-A′ shown in FIG. 21C.

Referring to FIG. 22A, a sidewall of the cell gate layer 141B1 may extend in the first direction DR1 along the second isolation structure 145A, and have unevenness. The cell gate layer 141B1 may surround the plurality of pillar structures 120.

The cell level active layer 161B may have a first sidewall extending in the first direction DR1 along the first isolation structure 135 and a second sidewall extending in the second direction DR2 while intersecting the first sidewall. The first sidewall may have unevenness along the first isolation structure 135. The second sidewall may be in contact with the cell gate layer 141B1 or the cell level contact conductive layer 141B2, and have unevenness. The cell level active layer 161B may extend between the pass gate insulating layer 163 and the insulative pillar structure 131.

A sidewall of the cell level contact conductive layer 141B2 may extend in the first direction DR1 along the third isolation structure 145B, and have unevenness.

FIG. 22B is a plan view of a second insulating layer 105B taken along line B-B′ shown in FIG. 21C.

Referring to FIG. 22B the second insulating layer 105B may continuously extend along the first region AR1, the second region AR2, and the third region AR3.

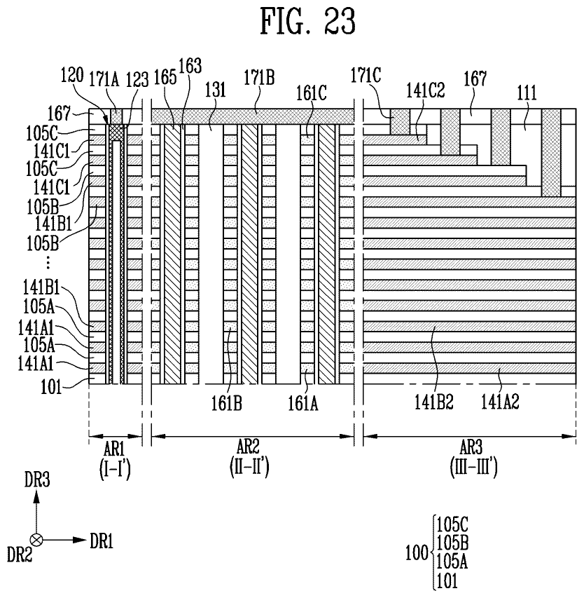

FIG. 23 illustrates some of processes continued after a process of forming the pass gate 165.

Referring to FIG. 23, a fourth insulating layer 167 may be formed to cover the filling insulating layer 111, the mold structure 100, the pillar structure 120, and the pass gate 165. Subsequently, the select line isolation structure SS shown in FIG. 3, 4A or 7 may be formed. After that, a conductive bit line contact structure 171A, a conductive gate contact structure 171B, and a plurality of global conductive patterns 171C may be formed to penetrate at least one of the fourth insulating layer 167, the filling insulating layer 111, and each insulating layer 105A, 105B or 105C of the mold structure 100. After that, subsequent processes such as a process of forming a bit line may be performed.

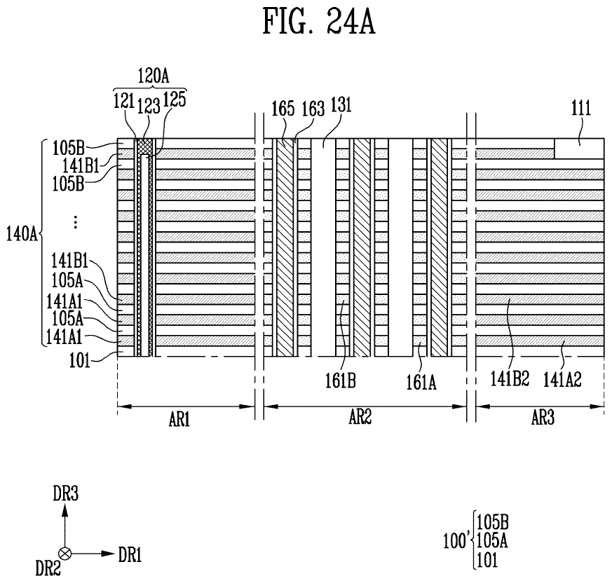

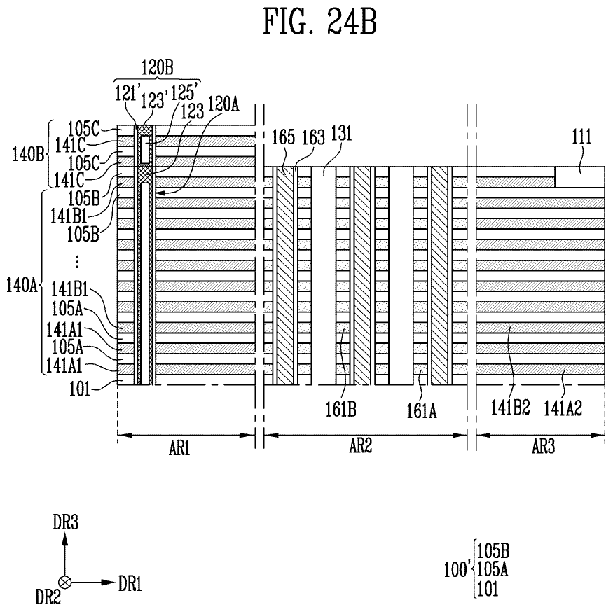

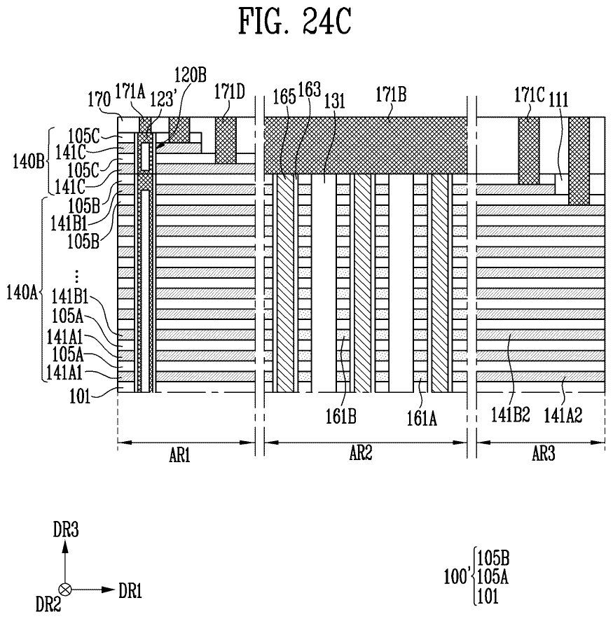

FIGS. 24A, 24B, and 24C are sectional views illustrating a method of manufacturing a semiconductor memory device in accordance with an embodiment of the present disclosure.

Referring to FIG. 24A, a lower stack structure 140A may be formed using the processes described with reference to FIGS. 12A, 12B, 13A, 13B, 14A, 14B, 15A, 15B, 16A, 16B, 17A, 17B, 17C, 18, 19, 20A, 20B, 21A, 21B, and 21C. The lower stack structure 140A may include a mold structure 100′ including an interposition insulating layer 101, at least one first insulating layer 105A, and a plurality of second insulating layers 105B, at least one source select gate layer 141A1, at least one source select level contact conductive layer 141A2, at least one source select level active layer 161A, a plurality of cell gate layers 141B1, a plurality of cell level contact conductive layers 141B2, and a plurality of cell level active layers 161B. When the lower structure 140A is formed in a stepped structure, the stepped structure may be covered with a first filling insulating layer 111.

A first region of the mold structure 100′, and the source select gate layer 141A1 and the plurality of cell gate layers 141B1, which overlap therewith, may be penetrated by the first pillar structure 120A, and the first pillar structure 120A may include a memory layer 121, a channel structure 123, and a core insulating layer 125. A second region AR2 of the mold structure 100′, and the source select level active layer 161 and the plurality of cell level active layers 161B, which overlap therewith, may be penetrated by a gate pillar structure including a pass gate insulating layer 163 and a pass gate 165, and an insulative pillar structure 131. The source select contact conductive layer 141A2 and the plurality of cell level contact conductive layers 141B2 may overlap with a third region AR3 of the mold structure 100′.

Referring to FIG. 24B, at least one drain select gate layer 141C and at least one third insulating layer 105C may be stacked on the lower stack structure 140A, thereby forming an upper stack structure 140B. The upper stack structure 140B may be etched in a stepped structure to open the second region AR2 and the third region AR3 of the mold structure 100′, and overlap with the first region AR1 of the mold structure 100′. Subsequently, a second pillar structure 120B may be formed, which penetrates the upper stack structure 140B. The second pillar structure 120B may be connected to the first pillar structure 120A. The second pillar structure 120B may include a gate insulating layer 121′, an upper channel structure 123′ and an upper core insulating layer 125′. Subsequently, a select isolation structure may be formed, which isolates the drain select gate layer 141C of the upper stack structure 140B into drain select lines.

Referring to FIG. 24C, an insulating structure 170 may be formed to cover the upper stack structure 140B, the lower stack structure 140A, and the filling insulating layer 111. Subsequently, a conductive bit line contact structure 171A, a conductive local contact structure 171D, a conductive gate contact structure 171B, and a plurality of global conductive patterns 171C may be formed to penetrate the insulating structure 170. The conductive bit line contact structure 171A may be connected to the channel structure 123′ of the second pillar structure 120B. The conductive local contact structure 171D may be connected to a drain select gate layer 141C corresponding thereto while penetrating the third insulating layer 105C. The conductive gate contact structure 171B may be connected to the pass gate 165. Each global conductive pattern 171C may be connected to a corresponding contact conductive layer among the source select level contact conductive layers 141A2 and the cell level contact conductive layers 141B2 while penetrating a corresponding insulating layer among the first insulating layers 105A and the second insulating layers 105B.

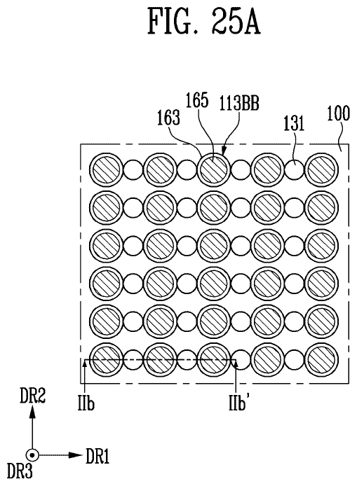

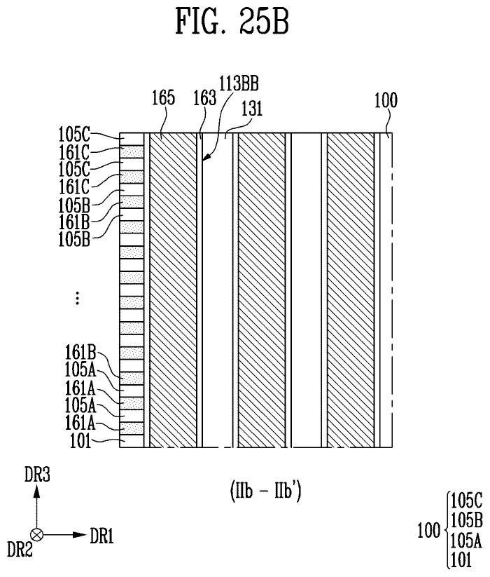

FIGS. 25A and 25B are views illustrating a semiconductor memory device in accordance with an embodiment of the present disclosure.

FIG. 25A is a plan view illustrating a second region of a mold structure 100, and FIG. 25B is a sectional view of the semiconductor memory device taken along line IIb-IIb′ shown in FIG. 25A.

Referring to FIGS. 25A and 25B, a mold structure 100, a plurality of active layers 161A, 161B, and 161C, a plurality of pass gate insulating layers 163, a plurality of pass gates 165, and a plurality of insulative pillar structure 131 may be formed using the processes described with reference to FIGS. 12A, 12B, 13A, 13B, 14A, 14B, 15A, 15B, 16A, 16B, 17A, 17B, 17C, 18, 19, 20A, 20B, 21A, 21B, and 21C.

As described with reference to FIG. 21A, the plurality of active layers 161A, 161B, and 161C may be formed in regions in which a plurality of sacrificial layers are removed through opened second holes, respectively. Before the plurality of sacrificial layers are removed, second holes may be enlarged such that the opened second holes expose the insulative pillar structures 131. “113BB” designates the enlarged second holes. After that, the plurality of sacrificial layers may be replaced with the plurality of active layers 161A, 161B, and 161C through the enlarged second holes 113BB. Accordingly, the pass gate insulating layer 163 may be connected to the insulative pillar structure 131.

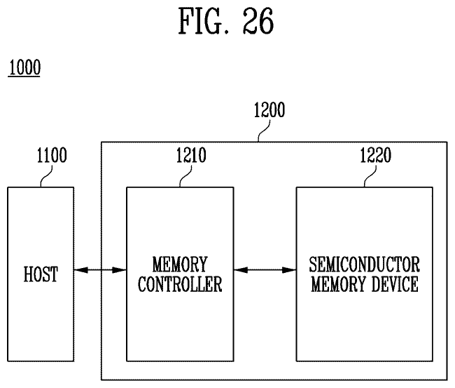

FIG. 26 is a block diagram illustrating an electronic system in accordance with embodiments of the present disclosure.

Referring to FIG. 26, the electronic system 1000 may be a computing system, a medical device, a communication device, a wearable device, a memory system, or the like. The electronic system 1000 may include a host 1100 and a storage device 1200.

The host 1100 may store data in the storage device 1200 or read data stored in the storage device 1200, based on an interface. The interface may include one or more of a Double Data Rate (DDR) interface, a Universal Serial Bus (USB) interface, a Multi-Media Card (MMC) interface, an embedded MMC (eMMC) interface, a Peripheral Component Interconnection (PCI) interface, a PCI-Express (PCI-E) interface, an Advanced Technology Attachment (ATA) interface, a Serial ATA (SATA) interface, a Parallel ATA (PATA) interface, a Small Computer System Interface (SCSI), an Enhanced Small Disk Interface (ESDI), an Integrated Drive Electronics (IDE) interface, a firewire interface, a Universal Flash Storage (UFS) interface, and a Non-Volatile Memory express (NVMe) interface.

The storage device 1200 may include a memory controller 1210 and a semiconductor memory device 1220. In an embodiment, the storage device 1200 may be a storage medium such as a Solid State Drive (SSD) or a Universal Serial Bus (USB) memory.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

In an embodiment, the semiconductor memory device 1220 may be a nonvolatile memory device. In an embodiment, the semiconductor memory device 1220 may include a plurality of conductive layers arranged in a vertical direction, a plurality of active layers connected to the plurality of conductive layers, a plurality of pass gates penetrating the plurality of active layers, and a plurality of pass gate insulating layers surrounding sidewalls of the plurality of pass gates, respectively.

In accordance with various embodiments of the present disclosure, a plurality of active layers disposed in a vertical direction and a pass gate penetrating the plurality of active layers may form a pass transistor group. Accordingly, in an embodiment, although a planar area occupied by the pass transistor group is not increased, the stacked number of active layers is increased corresponding to the stacked number of conductive layers, so that the conductive layers may be controlled. As a result, in an embodiment, the planar area occupied by the pass transistor group in a peripheral circuit structure may be decreased.

What is claimed is:

1. A semiconductor memory device comprising:
a plurality of cell pillar structures extending in a vertical direction, the plurality of cell pillar structures being arranged to be spaced apart from each other in a horizontal direction;
a word line stack structure surrounding the plurality of cell pillar structures, the word line stack structure including a plurality of cell gate layers arranged to be spaced apart from each other in the vertical direction;
a plurality of cell level contact conductive layers spaced apart from the plurality of cell gate layers in the horizontal direction, the plurality of cell level contact conductive layers being arranged to be spaced apart from each other in the vertical direction;
a plurality of cell level active layers connected to the plurality of cell gate layers, the plurality of cell level active layers extending in the horizontal direction to be connected to the plurality of cell level contact conductive layers, the plurality of cell level active layers being arranged to be spaced apart from each other in the vertical direction;
a plurality of pass gates spaced apart from each other in the horizontal direction, each of the plurality of pass gates penetrating the plurality of cell level active layers;
a plurality of pass gate insulating layers surrounding sidewalls of the plurality of pass gates, respectively; and
a plurality of insulative pillar structures alternately disposed one by one in the horizontal direction with the plurality of pass gates, the plurality of insulative pillar structures penetrating the plurality of cell level active layers.

2. The semiconductor memory device of claim 1, further comprising a plurality of conductive gate contact structures corresponding to a plurality of rows configured with the plurality of pass gates,
wherein two or more of the plurality of pass gates on each of the plurality of rows are arranged in a line in a first direction, and
wherein each of the plurality of conductive gate contact structures extends in the first direction to be connected to pass gates of a corresponding row among the plurality of rows.

3. The semiconductor memory device of claim 2, further comprising:
a conductive connection pattern connected to the plurality of conductive gate contact structures; and
a block select line connected to the plurality of pass gates via the plurality of conductive gate contact structures, and the conductive connection pattern.

4. The semiconductor memory device of claim 1, wherein the plurality of cell level active layers and the plurality of pass gates form a pass transistor group connected to the plurality of cell gate layers.

5. The semiconductor memory device of claim 1, further comprising a plurality of global conductive patterns connected to the plurality of cell level contact conductive layers, the plurality of global conductive patterns extending in the vertical direction.

6. The semiconductor memory device of claim 1, further comprising a source select gate layer and a drain select gate layer, spaced apart from each other in the vertical direction with the word line stack structure interposed therebetween, the source select gate layer and the drain select gate layer, surrounding the plurality of cell pillar structures.

7. The semiconductor memory device of claim 6, further comprising a select isolation structure penetrating the drain select gate layer, the select isolation structure isolating the drain select gate layer into at least two drain select lines surrounding different cell pillar structures among the plurality of cell pillar structures.

8. The semiconductor memory device of claim 7, further comprising:
a drain select level active layer extending in the horizontal direction from each of the at least two drain select lines, the drain select level active layer surrounding a corresponding pass gate among the plurality of pass gates; and
a drain select level contact conductive layer extending in the horizontal direction from the drain select level active layer,
wherein the select isolation structure extends to penetrate the drain select level active layer and the drain select level contact conductive layer.

9. The semiconductor memory device of claim 8, wherein the drain select level active layer and the corresponding pass gate form a pass transistor connected to a corresponding drain select line among the at least two drain select lines.

10. The semiconductor memory device of claim 8, further comprising a global conductive pattern connected to the drain select level contact conductive layer, the global conductive pattern extending in the vertical direction.

11. The semiconductor memory device of claim 7, further comprising at least two conductive local contact structures respectively extending in the vertical direction from the at least two drain select lines.

12. The semiconductor memory device of claim 11, further comprising:
a plurality of global conductive patterns respectively connected to the plurality of cell level contact conductive layers, the plurality of global conductive patterns extending in the vertical direction; and
a plurality of conductive gate contact structures corresponding to a plurality of rows configured with the plurality of pass gates, the plurality of conductive gate contact structures extending in a first direction to be connected to pass gates of a corresponding row among the plurality of rows,
wherein the plurality of conductive gate contact structures are disposed between the at least two conductive local contact structures and the plurality of global conductive patterns.

13. The semiconductor memory device of claim 6, further comprising:
a source select level active layer extending in the horizontal direction from the source select gate layer, the source select level active layer surrounding the plurality of pass gates; and
a source select level contact conductive layer extending in the horizontal direction from the source select level active layer.

14. The semiconductor memory device of claim 13, wherein the source select level active layer and the plurality of pass gates form a pass transistor group connected to the source select gate layer.

15. The semiconductor memory device of claim 13, further comprising a global conductive pattern connected to the source select level contact conductive layer, the global conductive pattern extending in the vertical direction.

16. A semiconductor memory device comprising:
a source layer having a first surface and a second surface, which face in directions opposite to each other and extend in a horizontal direction;
a bit line disposed to be spaced apart from the second surface of the source layer in a vertical direction;
a plurality of insulating layers including a local region, a global region spaced apart from the local region in the horizontal direction, and a pass transistor array region between the local region and the global region, the plurality of insulating layers being spaced apart from each other in the vertical direction between the second surface of the source layer and the bit line;
a plurality of first conductive layers alternately disposed one by one in the vertical direction with the plurality of insulating layers in the local region;
a plurality of cell pillar structures penetrating the plurality of first conductive layers and the plurality of insulating layers;
a plurality of active layers alternately disposed one by one in the vertical direction with the plurality of insulating layers in the pass transistor array region;
a plurality of pass gates each including a first end portion facing in the same direction as the first surface of the source layer and a second end portion facing in the same direction as the second surface of the source layer, each of the plurality of pass gates penetrating the plurality of active layers and the plurality of insulating layers; and
a plurality of pass gate insulating layers surrounding sidewalls of the plurality of pass gates, respectively,
wherein the first end portion of each of the plurality of pass gates is disposed closer to the plurality of insulating layers than the first surface of the source layer.

17. The semiconductor memory device of claim 16, further comprising first isolation structures penetrating the plurality of insulating layers in the pass transistor array region, the first isolation structures being spaced apart from each other with the plurality of pass gates and the plurality of active layers interposed between the first isolation structures.

18. The semiconductor memory device of claim 17, wherein the plurality of active layers are connected to the first conductive layers while being adjacent to the plurality of first conductive layers in a first direction, and
wherein the first isolation structures are adjacent to each other in a second direction intersecting the first direction.

19. The semiconductor memory device of claim 17, further comprising:
second isolation structures penetrating the plurality of insulating layers in the local region, the second isolation structures being respectively connected to the first isolation structures;
third isolation structures penetrating the plurality of insulating layers in the global region, the third isolation structures being respectively connected to the first isolation structures;
a plurality of second conductive layers alternately disposed one by one in the vertical direction with the plurality of insulating layers in the global region; and
a plurality of global conductive patterns extending in the vertical direction from the plurality of second conductive layers.

20. The semiconductor memory device of claim 19, wherein the plurality of cell pillar structures and the plurality of first conductive layers are disposed between the second isolation structures,
wherein the plurality of second conductive layers are disposed between the third isolation structures,
wherein the plurality of second conductive layers are connected to the plurality of active layers while being adjacent to the plurality of active layers in a first direction, and
wherein the first isolation structures are adjacent to each other in a second direction intersecting the first direction.

21. The semiconductor memory device of claim 19, wherein unevenness is formed at a sidewall of each of the plurality of insulating layers extending in the horizontal direction along the first isolation structures, the second isolation structures, and the third isolation structures.

22. The semiconductor memory device of claim 16, wherein the plurality of active layers and the plurality of pass gates form a pass transistor group connected to the plurality of first conductive layers.

23. The semiconductor memory device of claim 16, further comprising:
a plurality of conductive gate contact structures corresponding to a plurality of rows configured with the plurality of pass gates; and
a block select line connected to the plurality of conductive gate contact structures.

24. The semiconductor memory device of claim 23, wherein each of the plurality of pass gates has a cross-sectional structure having a major axis in a first direction and a minor axis in a second direction intersecting the plurality of rows,
wherein the plurality of pass gates are spaced apart from each other in the second direction, and
wherein the plurality of conductive gate contact structures are connected to the plurality of pass gates, respectively.

25. The semiconductor memory device of claim 23, wherein two or more of the plurality of pass gates on each of the plurality of rows are arranged in a line in a first direction, and
wherein each of the plurality of conductive gate contact structures extends in the first direction to be connected to two or more of the plurality of pass gates on each of the plurality of rows.

26. The semiconductor memory device of claim 16, further comprising a plurality of insulative pillar structures penetrating the plurality of insulating layers and the plurality of active layers in the pass transistor array region,
wherein the plurality of insulative pillar structures are alternately disposed one by one in the horizontal direction with the plurality of pass gates.
